(19) United States
(12) Patent Application Publication
(10) Pub. No.: US 2026/0129946 A1
(43) Pub. Date: May 7, 2026

(54) SEMICONDUCTOR STRUCTURE

(71) Applicant: Taiwan Semiconductor Manufacturing Company, Ltd., Hsinchu (TW)

(72) Inventors: KAI-CHUN CHANG, Hsinchu (TW); Yen-Chen LIAO, Hsinchu (TW); Ming-Chi FAN, Hsinchu (TW); Der-Ming KUO, Hsinchu (TW)

(73) Assignee: Taiwan Semiconductor Manufacturing Company, Ltd., Hsinchu (TW)

(21) Appl. No.: 18/938,016

(22) Filed: Nov. 5, 2024

(51) Int. Cl. H01L 29/49; H01L 21/28; H01L 29/40; H01L 29/78

(52) U.S. Cl. CPC H10D 64/671; H10D 30/65; H10D 64/111; H10D 64/01322

(57) ABSTRACT

A semiconductor structure includes a substrate and a contact field plate (CFP) on the substrate. The contact field plate includes an insulation layer on the substrate, a poly gate over the insulation layer, a first-type semiconductor doping region in the poly gate; and a second-type semiconductor doping region in the poly gate.

### BACKGROUND

A semiconductor structure includes a transistor and a contact field plate (CFP), wherein the contact field plate may discharge a voltage to a grounding potential for preventing the transistor from being damaged by the voltage. However, when the current is too large, the current may damage the transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of a cross-sectional view of a semiconductor structure according to an embodiment of the present disclosure;

FIG. 1B illustrates a schematic diagram of a cross-sectional view of a semiconductor structure according to another embodiment of the present disclosure;

FIG. 1C illustrates a schematic diagram of a cross-sectional view of a semiconductor structure according to another embodiment of the present disclosure;

FIG. 2A illustrates a schematic diagram of a cross-sectional view of a semiconductor structure according to another embodiment of the present disclosure;

FIG. 2B illustrates a schematic diagram of a cross-sectional view of a semiconductor structure according to another embodiment of the present disclosure;

FIG. 2C illustrates a schematic diagram of a cross-sectional view of a semiconductor structure according to another embodiment of the present disclosure;

FIG. 3 illustrates a schematic diagram of a cross-sectional view of a semiconductor structure according to another embodiment of the present disclosure;

FIGS. 4A to 4H illustrate schematic diagrams of manufacturing processes of the semiconductor structure in FIG. 1A;

FIGS. 5A to 5J illustrate schematic diagrams of manufacturing processes of the semiconductor structure in FIG. 1B;

FIGS. 6A to 6I illustrate schematic diagrams of manufacturing processes of the semiconductor structure in FIG. 2A;

FIGS. 7A to 7K illustrate schematic diagrams of manufacturing processes of the semiconductor structure in FIG. 2B; and

FIGS. 8A to 8I illustrate schematic diagrams of manufacturing processes of the semiconductor structure in FIG. 3.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

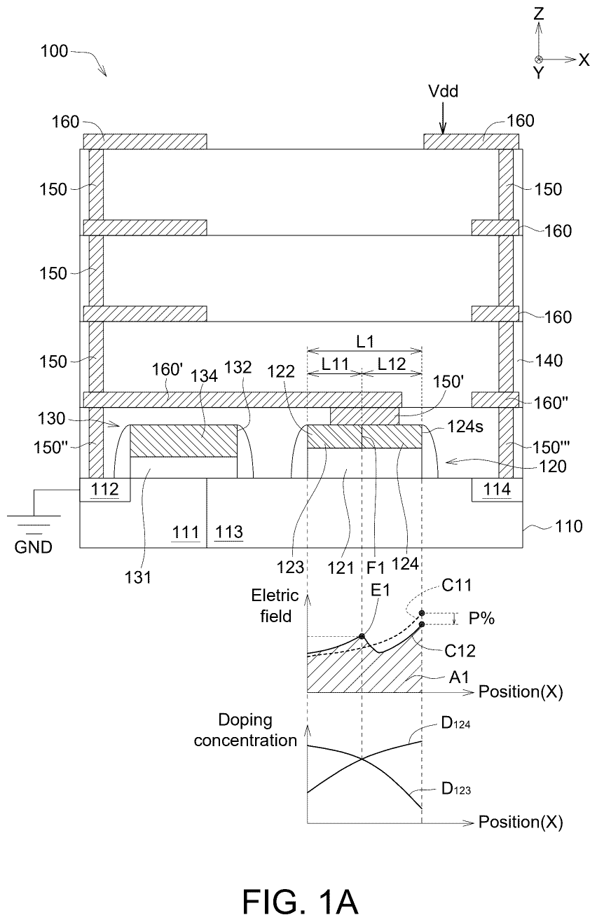

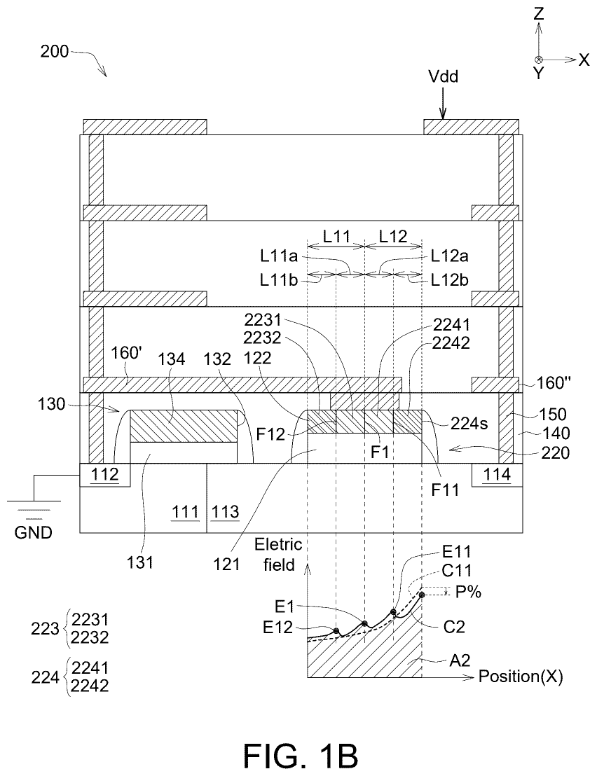

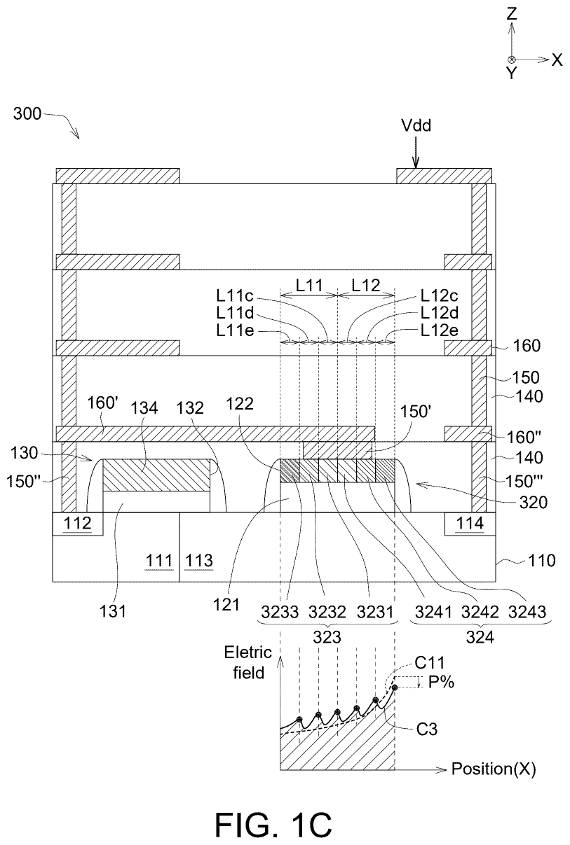

Referring to FIG. 1A, FIG. 1A illustrates a schematic diagram of a cross-sectional view of a semiconductor structure 100 according to an embodiment of the present disclosure. The semiconductor structure 100 may be applied to a LDMOS (Laterally Diffused Metal Oxide Semiconductor) of a PMIC (Power Management IC), for example.

As illustrated in FIG. 1A, the semiconductor structure 100 includes a substrate 110, a contact field plate 120, a transistor 130, at least on dielectric layer 140, at least on conductive via 150 and at least one conductive layer 160. The contact field plate 120 is disposed on the substrate 110 and includes an insulation layer 121, a poly gate 122, a first-type semiconductor doping region 123 and a second-type semiconductor doping region 124. The insulation layer 121 is disposed on the substrate 110, and the poly gate 122 is disposed over the insulation layer 121. The first-type semiconductor doping region 123 and the second-type semiconductor doping region 124 are disposed in the poly gate 122. The first-type semiconductor doping region 123 and the second-type semiconductor doping region 124 may split electrons deplete condition (split electric field) for increasing the voltage (for example, breakdown voltage) endurance capability of the contact field plate 120.

As illustrated in FIG. 1A, the first-type semiconductor doping region 123 and the second-type semiconductor doping region 124 may be disposed side-by-side. In the present embodiment, the transistor 130 in FIG. 1A is NMOS transistor, wherein the first-type semiconductor doping region 123 is a P-type semiconductor doping region (its built-in potential is negative voltage, and the greater the doping concentration is, the greater the negative voltage is), and the second-type semiconductor doping region 124 is a N-type semiconductor doping region (its built-in potential is positive voltage, and the greater the doping concentration is, the greater the positive voltage is).

In another embodiment, the transistor 130 in FIG. 1A may be PMOS transistor, wherein the first-type semiconductor doping region 123 is a N-type semiconductor doping region, and the second-type semiconductor doping region 124 is a P-type semiconductor doping region.

As illustrated in FIG. 1A, a curve D₁₂₃ represents a doping concentration distribution of the first-type semiconductor doping region 123, and a curve D₁₂₄ represents a doping concentration distribution of the second-type semiconductor doping region 124. In the present embodiment, the transistor 130 is NMOS transistor, the first-type semiconductor doping region 123 is boron doping region, and the second-type semiconductor doping region 124 is phosphorus doping region. In an embodiment, the doping concentration of the first-type semiconductor doping region 123 and the doping concentration of the second-type semiconductor doping region 124 may range between, for example, 1E18 and 1E22.

In another present embodiment, the transistor 130 is PMOS transistor, the first-type semiconductor doping region 123 is phosphorus doping region, and the second-type semiconductor doping region 124 is boron doping region.

As illustrated in FIG. 1A, the substrate 110 includes a first doping region 111, a second doping region 112, a third doping region 113 and a fourth doping region 114. The first doping region 111 is a semiconductor well, the second doping region 112 is a source region of the transistor 130, the third doping region 113 and the fourth doping region 114 are a drain region of the transistor 130, wherein the fourth doping region 114 has a doping concentration greater than that of the third doping region 113. In the present embodiment, the transistor 130 in FIG. 1A is NMOS transistor, wherein the first doping region 111 is a P-type well (PWL), the second doping region 112 is a N-type doping region (N+), the third doping region 113 is a N-type lightly doped drain (NLDD), and the fourth doping region 114 is a N-type doping region (N+).

In another embodiment, the transistor 130 is a PMOS transistor, wherein the first doping region 111 is a N-type well (NWL), the second doping region 112 is a P-type doping region (P+), the third doping region 113 is a P-type lightly doped drain (PDLL), and the fourth doping region 114 is a P-type doping region (P+).

As illustrated in FIG. 1A, the second doping region 112 may be electrically connected with a grounding potential GND. As a result, a driving voltage Vdd applied to the conductive layer 160 may be discharged to the grounding potential GND through the contact field plate 120.

As illustrated in FIG. 1A, the transistor 130 includes an insulation layer 131, a poly gate 132 and a semiconductor doping region 134, wherein the insulation layer 131 is disposed on the substrate 110, and the poly gate 132 is disposed over the insulation layer 131. The semiconductor doping region 134 is formed within the poly gate 132. In the present embodiment, the transistor 130 is a NMOS transistor, and the semiconductor doping region 134 is N-type semiconductor doping region. In another embodiment, the transistor 130 is a PMOS transistor, the semiconductor doping region 134 is P-type semiconductor doping region.

As illustrated in FIG. 1A, the driving voltage Vdd (for example, positive voltage when the transistor 130 is NMOS transistor) keeps applying to the fourth doping region 114 through the conductive layer 160 and the conductive via 150. When the transistor 130 is turned on, the driving voltage Vdd is supplied to a device (for example, speaker), and does not strike the transistor 130 and the contact field plate 120. When the transistor 130 is turned off, the driving voltage Vdd will strike the transistor 130; however, the contact field plate 120 may discharge the driving voltage Vdd to the grounding potential GND, and accordingly it may avoid the damage to the transistor 130 by the driving voltage Vdd. In the present embodiment, the first-type semiconductor doping region 123 and the second-type semiconductor doping region 124 may split the electric field and increase the voltage (for example, breakdown voltage) endurance capability of the contact field plate 120, and accordingly it may avoid the damage to the contact field plate 120 when a larger driving voltage Vdd is applied to the contact field plate 120. In addition, the driving voltage Vdd applied to the contact field plate 120 (through the conductive layer 160) may be discharged to the grounding potential GND through a conductive via 150′, a conductive layer 160′ and a conductive via 150″, wherein the conductive via 150′ electrically connects the poly gate 122 with the conductive layer 160′, and the conductive via 150″ electrically connects the conductive layer 160′ with the second doping region 112. In addition, a conductive via 150″′ electrically connects the fourth doping region 114 with a conductive layer 160″, and the driving voltage Vdd may be applied to the fourth doping region 114 through the conductive layer 160″ and the conductive via 150″′.

As illustrated in FIG. 1A, a curve C11 represents an electric field distribution of a contact field plate with single-type semiconductor doping region in the poly gate, and a curve C12 represents an electric field distribution of the contact field plate 120 with dual-type semiconductor doping region (that is, the first-type semiconductor doping region 123 and the second-type semiconductor doping region 124). The electric field may reflect a voltage difference between the driving voltage Vdd and a built-in potential of the semiconductor doping region (that is, first-type semiconductor doping region 123 and the second-type semiconductor doping region 124), wherein the greater the voltage difference between the driving voltage Vdd and the semiconductor doping region is, the greater the electric field (as illustrated curve C12) is. Compared to the curve C11, as illustrated in the curve C12, the voltage difference in an outer boundary 124s of the second-type semiconductor doping region 124 may reduce by P %, wherein P may be a positive real number, for example, equal to or greater than 16.7. As shown in the curve C12, a raised electric field E1 (due to the voltage difference increasing) in the contact field plate 120 corresponding to an interface F1 between the first-type semiconductor doping region 123 and the second-type semiconductor doping region 124 is generated, and accordingly an integral area (that is, voltage) A1 may be increased (the greater the integral area A1 is, the greater the voltage endurance capability of the contact field plate 120 is).

As illustrated in FIG. 1A, one of the dielectric layers 140 covers the contact field plate 120 and the transistor 130. One (150′) of the conductive vias 150 connecting one (160′) of the conductive layers 160 with the poly gate 122 is disposed within the dielectric layer 140, another (150″) of the conductive vias 150 connecting the second doping region 112 with one (160′) of the conductive layers 160 is disposed within the dielectric layer 140, and another (150″′) of the conductive vias 150 connecting the fourth doping region 114 with another (160″) of the conductive layers 160 is disposed within the dielectric layer 140. One of the conductive layers 160 is disposed on one of the dielectric layers 140, and the conductive vias 150 may connect the adjacent two of the conductive layers 160 through the dielectric layer 140.

As illustrated in FIG. 1A, the first-type semiconductor doping region 123 has a first length L11, and the second-type semiconductor doping region 124 has a second length L12. A ratio of the first length L11 to the second length L12 may range between, for example, 0.1 and 10, 0.2 and 5, etc. In an embodiment, the second length L12 is equal to the first length L11 (the ratio of the first length L11 to the second length L12 is equal to 1). As a result, the integral area A1 of the curve C12 may be increased or maximized (the greater the integral area A1 is, the greater the voltage endurance capability of the contact field plate 120 is). In an embodiment, the first length L11 and/or the second length L12 may range 0.05 micrometers and 10 micrometers.

As illustrated in FIG. 1A, the first-type semiconductor doping region 123 and the second-type semiconductor doping region 124 have a total length L1 (the sum of the first length L11 and the second length L12). The greater the total length L1 is, the greater the integral area A1 of the curve C12 is, and the greater the voltage endurance capability of the contact field plate 120 is.

Referring to FIG. 1B, FIG. 1B illustrates a schematic diagram of a cross-sectional view of a semiconductor structure 200 according to another embodiment of the present disclosure.

As illustrated in FIG. 1B, the semiconductor structure 200 includes the substrate 110, a contact field plate 220, the transistor 130, at least one dielectric layer 140, at least one conductive via 150 and at least one conductive layer 160. The contact field plate 220 is disposed on the substrate 110 and includes the insulation layer 121, the poly gate 122, a first-type semiconductor doping region 223 and a second-type semiconductor doping region 224. The insulation layer 121 is disposed on the substrate 110, and the poly gate 122 is disposed over the insulation layer 121. The first-type semiconductor doping region 223 and the second-type semiconductor doping region 224 are disposed in the poly gate 122. As a result, the first-type semiconductor doping region 223 and the second-type semiconductor doping region 224 may split electrons deplete condition (split electric field) for increasing the voltage (for example, breakdown voltage) endurance capability of the contact field plate 220.

In the present embodiment, the first-type semiconductor doping region 223 includes a plurality of first sub-regions, and the first sub-regions respectively have different doping concentrations. A first one of the first sub-regions is closer to the second-type semiconductor doping region 224 than a second one of the first sub-regions, and the first one of the first sub-regions has a doping concentration less than that of the second one of the first sub-regions.

For example, the first-type semiconductor doping region 223 includes a first sub-region 2231 (the first one) and a first sub-region 2232 (the second one), wherein the first sub-region 2231 is closer to the second-type semiconductor doping region 224 than the first sub-region 2232, and the first sub-region 2231 has the doping concentration less than that of the first sub-region 2232. In addition, the first sub-region 2231 and the first sub-region 2232 are disposed side-by-side.

In the present embodiment, the first one of the first sub-regions of the first-type semiconductor doping region 223 has a first sub-length equal to that of the second one of the first sub-regions of the first-type semiconductor doping region 223. For example, the first sub-region 2231 has a first sub-length L11a, the first sub-region 2232 has a first sub-length L11b, wherein a ratio of the first sub-length L11a to the first sub-length L11b may range between, for example, 0.1 and 10, 0.2 and 5, etc. In an embodiment, the first sub-length L11a is equal to the first sub-length L11b (the ratio of the first sub-length L11a to the first sub-length L11b is equal to 1). As a result, the integral area A1 of the curve C12 may be increased or maximized. In addition, a sum of the first sub-length L11a and the first sub-length L11b may be equal to the first length L11.

In the present embodiment, the second-type semiconductor doping region 224 includes a plurality of second sub-regions, and the second sub-regions respectively have different doping concentrations. A first one of the second sub-regions is closer to the first-type semiconductor doping region 223 than a second one of the second sub-regions, and the first one of the second sub-regions has a doping concentration less than that of the second one of the second sub-regions.

For example, the second-type semiconductor doping region 224 includes a second sub-region 2241 (the first one) and a second sub-region 2242 (the second one), wherein the second sub-region 2241 is closer to the first-type semiconductor doping region 223 than the second sub-region 2242, and the second sub-region 2241 has the doping concentration less than that of the second sub-region 2242. In addition, the second sub-region 2241 and the second sub-region 2242 are disposed side-by-side.

In the present embodiment, the first one of the second sub-regions of the second-type semiconductor doping region 224 has a second sub-length equal to that of the second one of the second sub-regions of the second-type semiconductor doping region 224. For example, the second sub-region 2241 has a second sub-length L12a, the second sub-region 2242 has a second sub-length L12b, wherein a ratio of the second sub-length L12a to the second sub-length L12b ranges between, for example, 0.1 and 10, 0.2 and 5, etc. In an embodiment, the second sub-length L12a is equal to the second sub-length L12b (the ratio of the second sub-length L12a to the second sub-length L12b is equal to 1). As a result, the integral area A1 of the curve C12 may be increased or maximized. In addition, a sum of the second sub-length L12a and the second sub-length L12b may be equal to the second length L12.

As illustrated in FIG. 1B, a curve C2 represents an electric field distribution of the contact field plate 220 with dual-type semiconductor doping region (that is, the first-type semiconductor doping region 223 and the second-type semiconductor doping region 224). Compared to the curve C11, as shown in the curve C2, the voltage difference in an outer boundary 224s of the second-type semiconductor doping region 224 may reduce by P %, wherein P may be a positive real number, for example, equal to or greater than 16.7. Due to the distribution of the first-type semiconductor doping region 223 and the second-type semiconductor doping region 224, as shown in the curve C2, a raised electric field E11 (due to the voltage difference increasing) in the contact field plate 220 corresponding to an interface F11 between the second sub-region 2242 and the second sub-region 2241 is generated, a raised electric field E1 (due to the voltage difference increasing) in the contact field plate 220 corresponding to the interface F1 between the second sub-region 2241 and the first sub-region 2231 is generated, and a raised electric field E12 (due to the voltage difference increasing) in the contact field plate 220 corresponding to an interface F12 between the first sub-region 2231 and the first sub-region 2232 is generated. As a result, an integral area A2 of the curve C2 may be increased, and it accordingly may increase the voltage (for example, breakdown voltage) endurance capability of the contact field plate 220.

Referring to FIG. 1C, FIG. 1C illustrates a schematic diagram of a cross-sectional view of a semiconductor structure 300 according to another embodiment of the present disclosure.

As illustrated in FIG. 1C, the semiconductor structure 300 includes the substrate 110, a contact field plate 320, the transistor 130, at least one dielectric layer 140, at least one conductive via 150 and at least one conductive layer 160. The contact field plate 320 is disposed on the substrate 110 and includes the insulation layer 121, the poly gate 122, a first-type semiconductor doping region 323 and a second-type semiconductor doping region 324. The insulation layer 121 is disposed on the substrate 110, and the poly gate 122 is disposed over the insulation layer 121. The first-type semiconductor doping region 323 and the second-type semiconductor doping region 324 are disposed in the poly gate 122. As a result, the first-type semiconductor doping region 323 and the second-type semiconductor doping region 324 may split electrons deplete condition (split electric field) for increasing the voltage (for example, breakdown voltage) endurance capability of the contact field plate 320.

In the present embodiment, the first-type semiconductor doping region 323 includes a plurality of first sub-regions, and the first sub-regions respectively have different doping concentrations. A first one of the first sub-regions is closer to the second-type semiconductor doping region 324 than a second one of the first sub-regions, and the second one of the first sub-regions is closer to the second-type semiconductor doping region 324 than a third one of the first sub-regions. The first one of the first sub-regions has a doping concentration less than that of the second one of the first sub-regions, and the second one of the first sub-regions has a doping concentration less than that of the third one of the first sub-regions.

For example, the first-type semiconductor doping regions 323 includes a first sub-region 3231 (the first one), a first sub-region 3232 (the second one) and a first sub-region 3233 (the third one), wherein the first sub-region 3231 is closer to the second-type semiconductor doping region 324 than the first sub-region 3232, the first sub-region 3232 is closer to the second-type semiconductor doping region 324 than the first sub-region 3233. The first sub-region 3231 has a doping concentration less than that of the first sub-region 3232, and the first sub-region 3232 has a doping concentration less than that of the first sub-region 3233. In addition, the first sub-region 3231, the first sub-region 3232 and the first sub-region 3233 may be disposed side-by-side.

In the present embodiment, the first one of the first sub-regions of the first-type semiconductor doping region 323 has a first sub-length equal to that of the second one of the first sub-regions of the first-type semiconductor doping region 323, and the second one of the first sub-regions of the first-type semiconductor doping region 323 has a first sub-length equal to that of the third one of the first sub-regions of the first-type semiconductor doping region 323.

For example, the first sub-region 3231 has a first sub-length L11c, the first sub-region 3232 has a first sub-length L11d and the first sub-region 3233 has a first sub-length L11e, wherein a ratio of the first sub-length L11c to the first sub-length L11d ranges between, for example, 0.1 and 10, 0.2 and 5, etc., and a ratio of the first sub-length L11d to the first sub-length L11e ranges between, for example, 0.1 and 10, 0.2 and 5, etc. In an embodiment, the first sub-length L11c may be equal to the first sub-length L11d (the ratio of the first sub-length L11c to the first sub-length L11d is equal to 1) and/or the first sub-length L11d is equal to the first sub-length L11e (the ratio of the first sub-length L11d to the first sub-length L11e is equal to 1). As a result, the integral area of the electric field may be increased or maximized. In addition, a sum of the first sub-length L11c, the first sub-length L11d and the first sub-length L11e is equal to the first length L11.

In the present embodiment, the second-type semiconductor doping region 324 includes a plurality of second sub-regions, and the second sub-regions respectively have different doping concentrations. A first one of the second sub-regions is closer to the first-type semiconductor doping region 323 than a second one of the second sub-regions, the second one of the second sub-regions is closer to the first-type semiconductor doping region 323 than a third one of the second sub-regions. The first one of the second sub-regions has a doping concentration less than that of the second one of the second sub-regions, and the second one of the second sub-regions has a doping concentration less than that of the third one of the second sub-regions.

For example, the second-type semiconductor doping region 324 includes a second sub-region 3241 (the first one), a second sub-region 3242 (the second one) and a second sub-region 3243 (the third one), wherein the second sub-region 3241 is closer to the first-type semiconductor doping region 323 than the second sub-region 3242, the second sub-region 3242 is closer to the first-type semiconductor doping region 323 than the second sub-region 3243. The second sub-region 3241 has a doping concentration less than that of the second sub-region 3242, and the second sub-region 3242 has a doping concentration less than that of the second sub-region 3243. In addition, the second sub-region 3241, the second sub-region 3242 and the second sub-region 3243 may be disposed side-by-side.

In the present embodiment, the first one of the second sub-regions of the second-type semiconductor doping region 324 has a second sub-length equal to that of the second one of the second sub-regions of the second-type semiconductor doping region 324, and the second one of the second sub-regions of the second-type semiconductor doping region 324 has a second sub-length equal to that of the third one of the second sub-regions of the second-type semiconductor doping region 324.

For example, the second sub-region 3241 has a second sub-length L12c, the second sub-region 3242 has a second sub-length L12d and the second sub-region 3243 has a second sub-length L12e, wherein a ratio of the second sub-length L12c to the second sub-length L12d ranges between, for example, 0.1 and 10, 0.2 and 5, etc., and a ratio of the second sub-length L12d to the second sub-length L12e ranges between, for example, 0.1 and 10, 0.2 and 5, etc. In an embodiment, the second sub-length L12c is equal to the second sub-length L12d (the ratio of the second sub-length L12c to the second sub-length L12d is equal to 1) and/or the second sub-length L12d is equal to the second sub-length L12e (the ratio of the second sub-length L12d to the second sub-length L12e is equal to 1). As a result, the integral area of the electric field may be increased or maximized. In addition, a sum of the second sub-length L12c, the second sub-length L12d and the second sub-length L12e is equal to the second length L12.

As illustrated in FIG. 1C, there is five interfaces among the first sub-regions 3231, 3232 and 3333 and the second sub-regions 3241, 3242 and 3343, and thus the contact field plate 320 may generate five raised electric field (due to the voltage difference increasing) to increase the voltage (for example, breakdown voltage) endurance capability of the contact field plate 320.

As described above, a first-type semiconductor doping region and a second-type semiconductor doping region may be formed within the poly gate 122, wherein the first-type semiconductor doping region has a concentration, the concentration of a first sub-region of the first-type semiconductor doping region is proportional to a distance between such first sub-region of the first-type semiconductor doping region and the second-type semiconductor doping region, and the second-type semiconductor doping region has a concentration, the concentration of a second sub-region of the second-type semiconductor doping region is proportional to a distance between such second sub-region of the second-type semiconductor doping region and the first-type semiconductor doping region. In another embodiment, each first-sub region of the first-type semiconductor doping region has a first sub-length, wherein the first sub-lengths of the first-sub regions may be equal or different, and each second-sub region of the second-type semiconductor doping region has a second sub-length, wherein the first sub-lengths of the second-sub regions may be equal or different. In addition, the first-type semiconductor doping region may include at least one first sub-region, and the second-type semiconductor doping region may include at least one second sub-region, wherein the number of the first sub-regions may be equal to or greater than 1, and the number of the second sub-regions may be equal to or greater than 1. The number of the first sub-regions and the number of the second sub-regions may be equal to different.

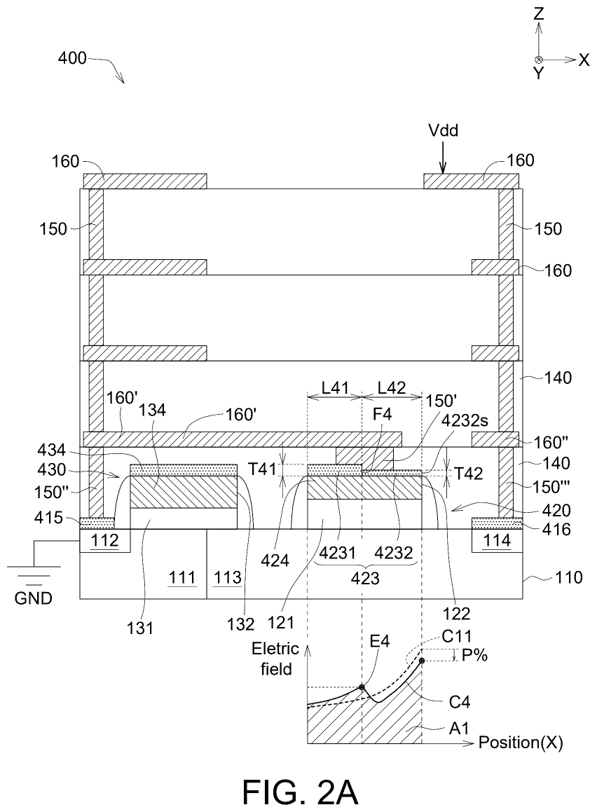

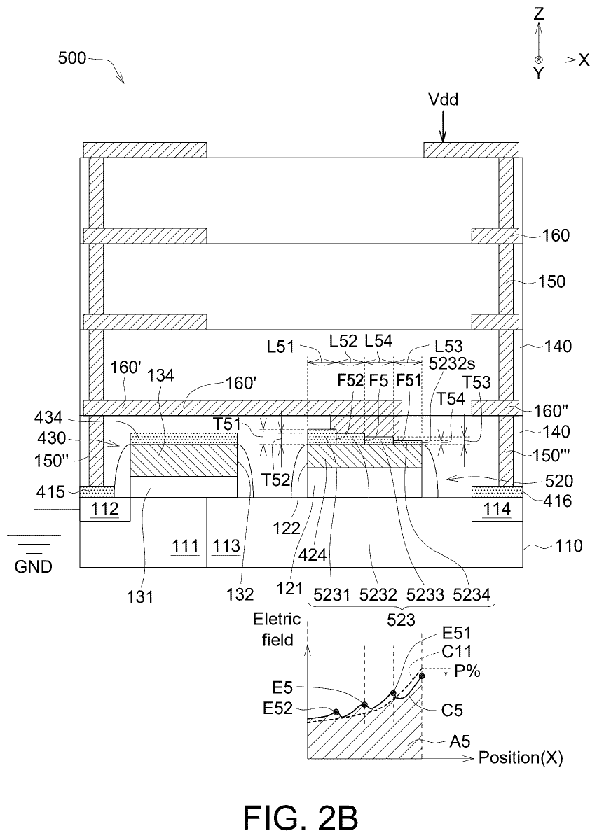

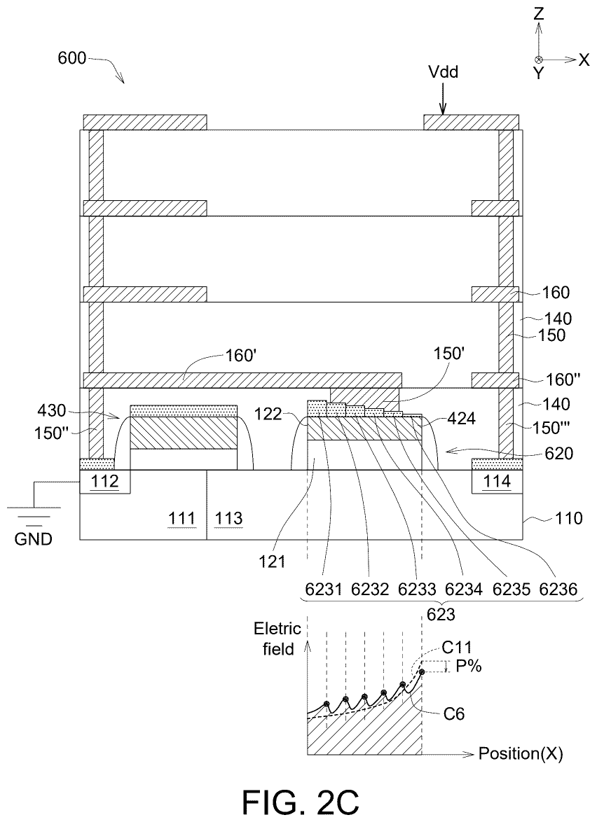

Referring to FIG. 2A, FIG. 2A illustrates a schematic diagram of a cross-sectional view of a semiconductor structure 400 according to another embodiment of the present disclosure.

As illustrated in FIG. 2A, the semiconductor structure 400 includes the substrate 110, a contact field plate 420, the transistor 130, at least one dielectric layer 140, at least one conductive via 150 and at least one conductive layer 160. The contact field plate 420 is disposed on the substrate 110 and includes the insulation layer 121, the poly gate 122, a silicide 423 and a semiconductor doping region 424. The insulation layer 121 is disposed on the substrate 110, and the poly gate 122 is disposed over the insulation layer 121. The semiconductor doping region 424 is disposed within the poly gate 122. When the transistor 130 is a NMOS transistor, the semiconductor doping region 424 is N-type semiconductor doping region. When the transistor 130 is a PMOS transistor, the semiconductor doping region 424 is P-type semiconductor doping region.

As illustrated in FIG. 2A, the silicide 423 is disposed over the poly gate 122. The silicide 423 includes a first silicide portion 4231 and a second silicide portion 4232, wherein the first silicide portion 4231 has a first thickness T41, and the second silicide portion 4232 has a second thickness T42. The first thickness T41 and the second thickness T42 are different. The silicide 423 with different thickness may split electrons deplete condition (split electric field) for increasing the voltage (for example, breakdown voltage) endurance capability of the contact field plate 420.

In the present embodiment, the silicide 423 is a two-stage silicide (that is, the first silicide portion 4231 and the second silicide portion 4232). In an embodiment, the silicide portion may be formed of a material including, for example, Ti, Co, Ni, Pt, W, etc.

As illustrated in FIG. 2A, the silicide 423 may be formed of a metal material and silicon material. The greater the thickness of the silicide 423, and the greater the negative potential of the silicide 423 is (equivalent to the higher the doping concentration of P-type semiconductive doping region is) or the less the positive potential of the silicide 423 is (equivalent to the higher the doping concentration of N-type semiconductive doping region is).

As illustrated in FIG. 2A, in the present embodiment, the transistor 130 is, for example, NMOS transistor. The first silicide portion 4231 is closer to the transistor 130 than the second silicide portion 4232, and the first thickness T41 is greater than the second thickness T42. In other words, when the transistor 130 is a NMOS transistor, the closer the distance between the silicide portion and the transistor 130, the thicker the silicide portion is. In addition, in an embodiment, the first thickness T41 and/or the second thickness T42 may range between, for example, 1 nanometer and 100 nanometers.

In another embodiment, the transistor 130 is a PMOS transistor. The first silicide portion 4231 is closer to the transistor 130 than the second silicide portion 4232, and the first thickness T41 is less than the second thickness T42. In other words, when the transistor 130 is PMOS transistor, the closer the distance between the silicide portion and the transistor 130, the thinner the silicide portion is.

As illustrated in FIG. 2A, the contact field plate 420 with different thickness of the silicide 423 may generate an electric field distribution similar to that of the contact field plate 120 in FIG. 1A. Furthermore, the curve C11 represents the electric field distribution of a contact field plate with uniform thickness of the silicide, and a curve C4 represents an electric field distribution of the contact field plate 420 with different thickness of the silicide 423. The electric field may reflect a voltage difference between the driving voltage Vdd and a built-in potential of the silicide 423, wherein the greater the voltage difference between the driving voltage Vdd and the silicide 423 is, the greater the electric field (as illustrated curve C4) is. Compared to the curve C11, as illustrated in the curve C4, the voltage difference in an outer boundary 4232s of the second silicide portion 4232 may reduce by P %, wherein P may be a positive real number, for example, equal to or greater than 16.7. As shown in the curve C4, a raised electric field E4 (due to the voltage difference increasing) in the contact field plate 420 corresponding to an interface F4 between the first silicide portion 4231 and the second silicide portion 4232 is generated, and accordingly an integral area A4 may be increased (the greater the integral area A4 is, the greater the voltage endurance capability of the contact field plate 420 is).

As illustrated in FIG. 2A, the first silicide portion has a first length, the second silicide portion has a second length, and the first length is equal to the second length. A ratio of the first length to the second length may range between, for example, 0.1 and 10, 0.2 and 5, etc. In an embodiment, the first silicide portion 4231 has a first length L41, the second silicide portion 4232 has a second length L42, and the first length L41 is equal to the second length L42 (the ratio of the first length L41 to the second length L42 is equal to 1). As a result, the integral area A4 of the electric field may be increased or maximized (the greater the integral area A4 is, the greater the voltage endurance capability of the contact field plate 420 is). In addition, the value of the first length L41 may be equal to that of the first length L11 in FIG. 1A, and the value of the second length L42 may be equal to that of the second length L12 in FIG. 1A.

Referring to FIG. 2B, FIG. 2B illustrates a schematic diagram of a cross-sectional view of a semiconductor structure 500 according to another embodiment of the present disclosure.

As illustrated in FIG. 2B, the semiconductor structure 500 includes the substrate 110, a contact field plate 520, the transistor 130, at least one dielectric layer 140, at least one conductive via 150 and at least one conductive layer 160. The contact field plate 520 is disposed on the substrate 110 and includes the insulation layer 121, the poly gate 122, a silicide 523 and a semiconductor doping region 424. The insulation layer 121 is disposed on the substrate 110, and the poly gate 122 is disposed over the insulation layer 121. The semiconductor doping region 424 is disposed within the poly gate 122. When the transistor 130 is a NMOS transistor, the semiconductor doping region 424 is N-type semiconductor doping region. When the transistor 130 is a PMOS transistor, the semiconductor doping region 424 is P-type semiconductor doping region.

As illustrated in FIG. 2B, the silicide 523 is disposed over the poly gate 122. The silicide 523 includes a first silicide portion 5231, a second silicide portion 5232, a third silicide portion 5233 and a fourth silicide portion 5234, wherein the first silicide portion 5231 has a first thickness T51, the second silicide portion 5232 has a second thickness T52, the third silicide portion 5233 has a third thickness T53 and the fourth silicide portion 5234 has a fourth thickness T54. The first thickness T51, the second thickness T52, the third thickness T53 and the fourth thickness T54 are different. The silicide 523 with different thickness may split electrons deplete condition (split electric field) for increasing the voltage (for example, breakdown voltage) endurance capability of the contact field plate 520.

In the present embodiment, the silicide 523 is a four-stage silicide (that is, the first silicide portion 5231, the second silicide portion 5232, the third silicide portion 5233 and the fourth silicide portion 5234).

As illustrated in FIG. 2B, the silicide 523 may be formed of a metal material and silicon material. The greater the thickness of the silicide 523, and the greater the negative potential of the silicide 523 is (equivalent to the higher the doping concentration of P-type semiconductive doping region is) or the less the positive potential of the silicide 523 is (equivalent to the higher the doping concentration of N-type semiconductive doping region is).

As illustrated in FIG. 2B, in the present embodiment, the transistor 130 is, for example, NMOS transistor. The first silicide portion 5231 is closer to the transistor 130 than the second silicide portion 5232, and the first thickness T51 is greater than the second thickness T52. The second silicide portion 5232 is closer to the transistor 130 than the third silicide portion 5233, and the second thickness T52 is greater than the third thickness T53. The third silicide portion 5233 is closer to the transistor 130 than the fourth silicide portion 5234, and the third thickness T53 is greater than the fourth thickness T54. In other words, when the transistor 130 is NMOS transistor, the closer the distance between the silicide portion and the transistor 130, the thicker the silicide portion is.

In another embodiment, the transistor 130 is, for example, PMOS transistor. The first silicide portion 5231 is closer to the transistor 130 than the second silicide portion 5232, and the first thickness T51 is less than the second thickness T52. The second silicide portion 5232 is closer to the transistor 130 than the third silicide portion 5233, and the second thickness T52 is less than the third thickness T53. The third silicide portion 5233 is closer to the transistor 130 than the fourth silicide portion 5234, and the third thickness T53 is less than the fourth thickness T54. In other words, when the transistor 130 is PMOS transistor, the closer the distance between the silicide portion and the transistor 130, the thinner the silicide portion is.

As illustrated in FIG. 2B, the contact field plate 520 with different thickness of the silicide 523 may generate an electric field distribution similar to that of the contact field plate 220 in FIG. 1B. Furthermore, the curve C11 represents the electric field distribution of a contact field plate with uniform thickness of the silicide, and a curve C5 represents an electric field distribution of the contact field plate 520 with different thickness of the silicide 523. The electric field may reflect a voltage difference between the driving voltage Vdd and a built-in potential of the silicide 523, wherein the greater the voltage difference between the driving voltage Vdd and the silicide 523 is, the greater the electric field (as illustrated curve C5) is. Compared to the curve C11, as illustrated in the curve C5, the voltage difference in an outer boundary 5232s of the second silicide portion 5232 may reduce by P %, wherein P may be a positive real number for example, equal to or greater than 16.7. As shown in the curve C5, a raised electric field E51 (due to the voltage difference increasing) in the contact field plate 520 corresponding to an interface F51 between the third silicide portion 5233 and the fourth silicide portion 5234 is generated, a raised electric field E1 (due to the voltage difference increasing) in the contact field plate 520 corresponding to the interface F5 between the second silicide portion 5232 and the third silicide portion 5233 is generated, and a raised electric field E52 (due to the voltage difference increasing) in the contact field plate 520 corresponding to an interface F52 between the first silicide portion 5231 and the second silicide portion 5232 is generated. As a result, an integral area A5 of the curve C5 may be increased, and it accordingly may increase the voltage (for example, breakdown voltage) endurance capability of the contact field plate 520.

As illustrated in FIG. 2B, the first silicide portion has a first length, the second silicide portion has a second length, the third silicide portion has a third length, the fourth silicide portion has a fourth length. The first length, the second length, third length and the fourth length are equal. In an embodiment, a ratio of the adjacent two length ranges between, for example, 0.1 and 10, 0.2 and 5, etc. In an embodiment, the first silicide portion 5231 has a first length L51, the second silicide portion 5232 has a second length L52, the third silicide portion 5233 has a third length L53 and the fourth silicide portion 5234 has a fourth length L54, wherein the first length L51, the second length L52, the third length L53 and the fourth length L54 may be equal. As a result, the integral area A5 of the electric field may be increased or maximized (the greater the integral area is, the greater the voltage endurance capability of the contact field plate 520 is). In addition, a sum of the first length L51 and the second length L52 may be equal to the first length L11 in FIG. 1A, and a sum of the third length L53 and the fourth length L54 may be equal to the second length L12 in FIG. 1A.

Referring to FIG. 2C, FIG. 2C illustrates a schematic diagram of a cross-sectional view of a semiconductor structure 600 according to another embodiment of the present disclosure.

As illustrated in FIG. 2C, the semiconductor structure 600 includes the substrate 110, a contact field plate 620, the transistor 130, at least one dielectric layer 140, at least one conductive via 150 and at least one conductive layer 160. The contact field plate 620 is disposed on the substrate 110 and includes the insulation layer 121, the poly gate 122, a silicide 623 and a semiconductor doping region 424. The insulation layer 121 is disposed on the substrate 110, and the poly gate 122 is disposed over the insulation layer 121. The silicide 523 is disposed over the poly gate 122. When the transistor 130 is NMOS transistor, the semiconductor doping region 424 is N-type semiconductor doping region. When the transistor 130 is PMOS transistor, the semiconductor doping region 424 is P-type semiconductor doping region.

As illustrated in FIG. 2B, the silicide 623 is disposed over the poly gate 122. The silicide 623 includes a first silicide portion 6231, a second silicide portion 6232, a third silicide portion 6233, a fourth silicide portion 6234, a fifth silicide portion 6235 and a sixth silicide portion 6236. The first silicide portion 6231, the second silicide portion 6232, the third silicide portion 6233, the fourth silicide portion 6234, the fifth silicide portion 6235 and the sixth silicide portion 6236 have different thickness. The silicide 623 has different thickness may split electrons deplete condition (split electric field) for increasing the voltage (for example, breakdown voltage) endurance capability of the contact field plate 620.

In the present embodiment, the silicide 623 is a six-stage silicide (that is, the first silicide portion 6231, the second silicide portion 6232, the third silicide portion 6233, the fourth silicide portion 6234, the fifth silicide portion 6235 and the sixth silicide portion 6236).

As illustrated in FIG. 2C, the silicide 623 may be formed of a metal material and silicon material. The greater the thickness of the silicide 623, and the greater the negative potential of the silicide 623 is (equivalent to the higher the doping concentration of P-type semiconductive doping region is) or the less the positive potential of the silicide 623 is (equivalent to the higher the doping concentration of N-type semiconductive doping region is).

In the present embodiment, the transistor 130 is a NMOS transistor, and the closer the distance between the silicide portion and the transistor 130, the thicker the silicide portion is. In another embodiment, when the transistor 130 is PMOS transistor, the closer the distance between the silicide portion and the transistor 130, the thinner the silicide portion is.

As illustrated in FIG. 2C, as shown in a curve C6, the contact field plate 620 with dual-type semiconductor doping region may generate an electric field distribution similar to that of the contact field plate 320. For example, there is five interfaces among the first silicide portion 6231, the second silicide portion 6232, the third silicide portion 6233, the fourth silicide portion 6234, the fifth silicide portion 6235 and the sixth silicide portion 6236, and thus the contact field plate 620 may generate five raised electric field (due to the voltage difference increasing) to increase the voltage (for example, breakdown voltage) endurance capability of the contact field plate 620.

As illustrated in FIG. 2C, the first silicide portion 6231, the second silicide portion 6232, the third silicide portion 6233, the fourth silicide portion 6234, the fifth silicide portion 6235 and a sixth silicide portion 6236 each has a length, and a ratio of the adjacent two length may range between, for example, 0.1 and 10, 0.2 and 5, etc., for example, 1.

As described above, the silicide may be a J-stage silicide, wherein J is positive integer equal to or greater than 2. The silicide includes J silicide portion each having a thickness, wherein the thickness of each silicide portion is different. In an embodiment, the transistor 130 is NMOS transistor, the closer to the transistor 130, the thicker the silicide portion is. In another embodiment, the transistor 130 is a PMOS transistor, the closer to the transistor 130, the thinner the silicide portion is. In addition, each silicide portion of the silicide has a length, wherein the ratio of the lengths of the adjacent two silicide portions may range between, for example, 0.1 and 10, 0.2 and 5, etc., for example, 1.

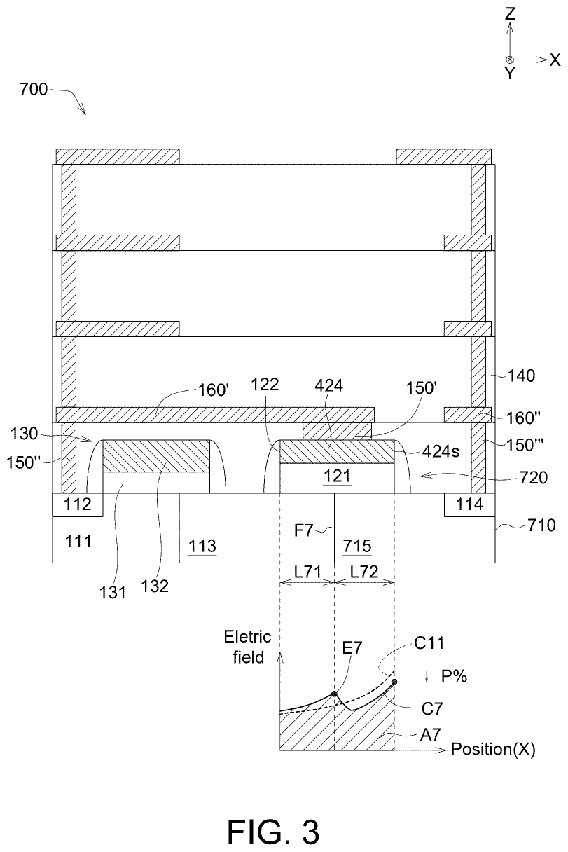

As illustrated in FIG. 3, FIG. 3 illustrates a schematic diagram of a cross-sectional view of a semiconductor structure 700 according to another embodiment of the present disclosure. The semiconductor structure 700 includes a substrate 710, a contact field plate 720, the transistor 130, at least one dielectric layer 140, at least one conductive via 150 and at least one conductive layer 160. The contact field plate 720 is disposed on the substrate 710 and includes the insulation layer 121, the poly gate 122 and the semiconductor doping region 424. The insulation layer 121 is disposed on the substrate 710, and the poly gate 122 is disposed over the insulation layer 121.

As illustrated in FIG. 3, the substrate 710 includes a plurality of doping regions beneath the contact field plate 720, and the doping regions have different doping concentrations. The substrate 710 with the regions of different doping concentrations may split electrons deplete condition (split electric field) for increasing the voltage (for example, breakdown voltage) endurance capability of the contact field plate 720.

Furthermore, the substrate 710 includes the first doping region 111, the second doping region 112, the third doping region 113, the fourth doping region 114 and a fifth doping region 715, wherein the third doping region 113 and the fifth doping region 715 are located beneath the contact field plate 720. The first doping region 111 is a semiconductor well, the second doping region 112 is a source region of the transistor 130, and the third doping region 113, the fourth doping region 114 and the fifth doping region 715 are a drain region of the transistor 130, wherein the fourth doping region 114 has a doping concentration greater than that of the third doping region 113.

In the present embodiment, the transistor 130 is NMOS transistor, wherein the first doping region 111 is a P-type well (PWL), the second doping region 112 is a N-type doping region (N+), the third doping region 113 is a N-type lightly doped drain (NLDD), the fourth doping region 114 is a N-type doping region (N+), and the fifth doping region 715 is a N-type doped drain (NDD), wherein the fourth doping region 114 has the doping concentration greater than that of the fifth doping region 715, and the fifth doping region 715 has the doping concentration greater than that of the third doping region 113. In an embodiment, the NLDD and/or the NDD may have a doping concentration ranging between, for example, 1E10 and 1E19.

In another embodiment, the transistor 130 is a PMOS transistor, wherein the first doping region 111 is a N-type well (NWL), the second doping region 112 is a P-type doping region (P+), the third doping region 113 is a P-type lightly doped drain (PDLL), the fourth doping region 114 is a P-type doping region (P+), and the fifth doping region 715 is a P-type doped drain (PDD), wherein the fourth doping region 114 has the doping concentration greater than that of the fifth doping region 715, and the fifth doping region 715 has the doping concentration greater than that of the third doping region 113.

As illustrated in FIG. 3, the contact field plate 720 has a first length L71 and a second length L72, the first length L71 overlap the first one (for example, the third doping region 113) of the doping regions, the second length L72 overlap the second one (for example, the fifth doping region 715) of the doping regions. A ratio of the first length L71 to the second length L72 may range between, for example, 0.1 and 10, 0.2 and 5, etc. In an embodiment, the second length L72 is equal to the first length L71 (the ratio of the first length L71 to the second length L72 is equal to 1). As a result, the integral area A7 of the curve C7 may be increased or maximized (the greater the integral area A7 is, the greater the voltage endurance capability of the contact field plate 720 is). In an embodiment, the first length L71 and/or the second length L72 may range 0.05 micrometers and 10 micrometers.

As illustrated in FIG. 3, the curve C11 represents an electric field distribution of a contact field plate under the substrate 110, and a curve C7 represents an electric field distribution of the contact field plate 720 under the substrate 710. The electric field may reflect a voltage difference between the driving voltage Vdd and a built-in potential of the doping regions of the substrate 710 (that is, the third doping region 113 and the fifth doping region 715), wherein the greater the voltage difference between the driving voltage Vdd and the doping region is, the greater the electric field (as illustrated curve C7) is. Compared to the curve C11, as illustrated in the curve C7, the voltage difference in an outer boundary 424s of the semiconductor doping region 424 may reduce by P %, wherein P may be a positive real number, for example, equal to or greater than 16.7. As shown in the curve C7, a raised electric field E7 (due to the voltage difference increasing) in the contact field plate 720 corresponding to an interface F1 between the third doping region 113 and the fifth doping region 715 is generated, and accordingly an integral area (that is, voltage) A7 may be increased (the greater the integral area A7 is, the greater the voltage endurance capability of the contact field plate 720 is).

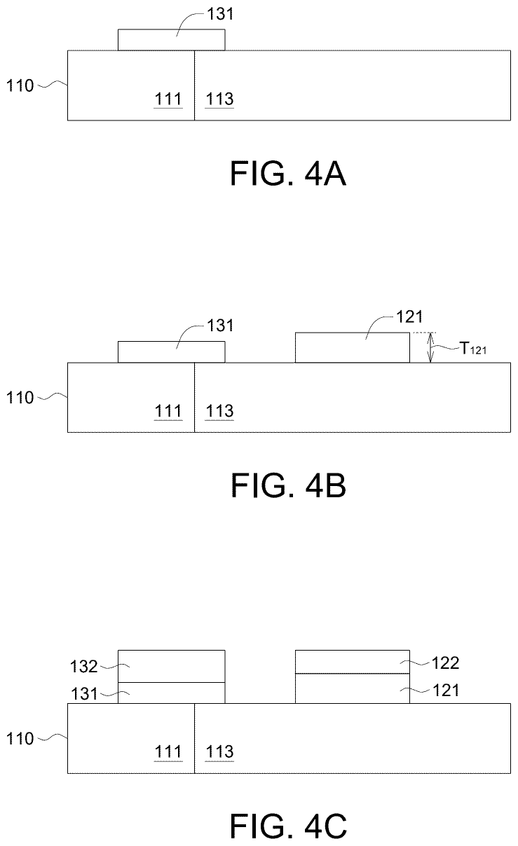

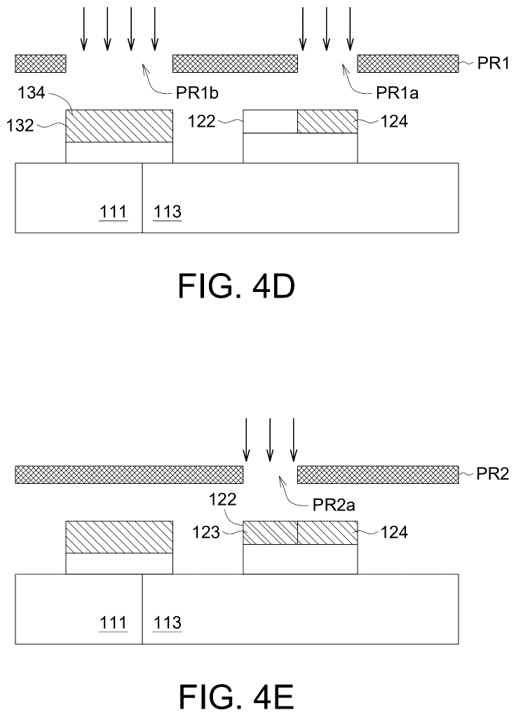

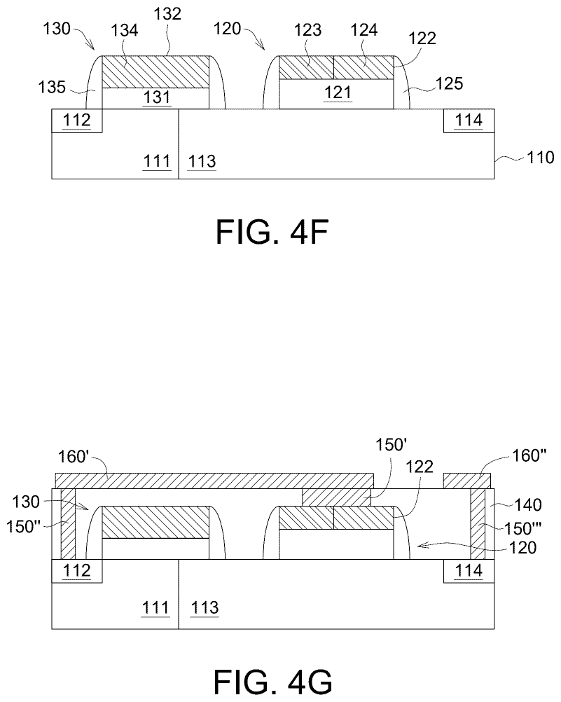

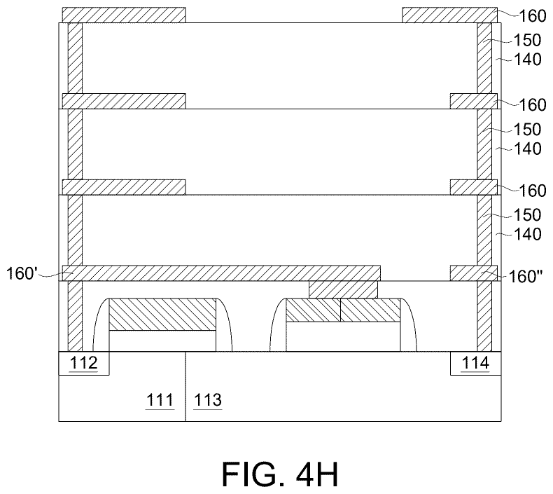

Referring to FIGS. 4A to 4H, FIGS. 4A to 4H illustrate schematic diagrams of manufacturing processes of the semiconductor structure 100 in FIG. 1A.

As illustrated in FIG. 4A, the substrate 110 including the first doping region 111 and the third doping region 113 is provided. Then, the insulation layer 131 is formed on the substrate 110 by using, for example, deposition, photolithography, etching, etc.

As illustrated in FIG. 4B, the insulation layer 121 is formed on the third doping region 113 of the substrate 110 by using, for example by using, for example, deposition, photolithography, etching, etc. In an embodiment, the insulation layer 121 has a thickness T121 ranging between, for example, 5 nanometers and 500 nanometers.

As illustrated in FIG. 4C, the poly gate 132 over the insulation layer 131 by using, for example by using, for example, deposition, photolithography, etching, etc. The poly gate 122 over the insulation layer 121 by using, for example by using, for example, deposition, photolithography, etching, etc. The poly gate may be formed of poly silicon, for example.

As illustrated in FIG. 4D, the second-type semiconductor doping region 124 is formed within a first portion of the poly gate 122 by using, for example, implant. The semiconductor doping region 134 is formed within the poly gate 132 by using, for example, implant. The second-type semiconductor doping region 124 and the semiconductor doping region 134 may be formed through a mask PR1, wherein the mask PR1 has a first penetration zone PR1a and a second penetration zone PR1b, the second-type semiconductor doping region 124 is formed through the first penetration zone PR1a, and the semiconductor doping region 134 is formed through the second penetration zone PR1b. The mask is, for example, a patterned photoresist.

As illustrated in FIG. 4E, the first-type semiconductor doping region 123 is formed within a second portion of the poly gate 122 by using, for example, implant. The first-type semiconductor doping region 123 may be formed through a mask PR2, wherein the mask PR2 has a penetration zone PR2a, and the first-type semiconductor doping region 123 is formed through the penetration zone PR2a.

As illustrated in FIG. 4F, a spacer 135 covering a lateral surface of the insulation layer 131 and the poly gate 132 is formed by using, deposition, photolithography, etching, etc. A spacer 125 covering a lateral surface of the insulation layer 121 and the poly gate 122 is formed by using, deposition, photolithography, etching, etc. The second doping region 112 in the first doping region 111 and the fourth doping region 114 in the third doping region 113 are formed by implant. So far, the contact field plate 120 and the transistor 130 are formed.

As illustrated in FIG. 4G, the dielectric layer 140 covering the contact field plate 120 and the transistor 130 is formed by using, for example, deposition, CMP. Then, the conductive via 150′, the conductive via 150″ and the conductive via 150″′ are formed in the dielectric layer 140 by using, for example, photolithography, deposition, etching, CMP, etc. Then, the conductive layer 160′ on the dielectric layer 140 is formed by using, for example, deposition, photolithography, etching, etc.

The conductive via 150′ electrically connects the poly gate 122 with the conductive layer 160′, and the conductive via 150″ electrically connects the conductive layer 160′ with the second doping region 112. In addition, the conductive via 150″′ electrically connects the fourth doping region 114 with the conductive layer 160″, and the driving voltage Vdd may be applied to the fourth doping region 114 through the conductive layer 160″ and the conductive via 150″′.

As illustrated in FIG. 4H, at least one dielectric layers 140, at least one conductive layer 160 and at least one conductive via 150 are formed on the bottommost dielectric layers 140, wherein the conductive via 150 connects two conductive layers 160.

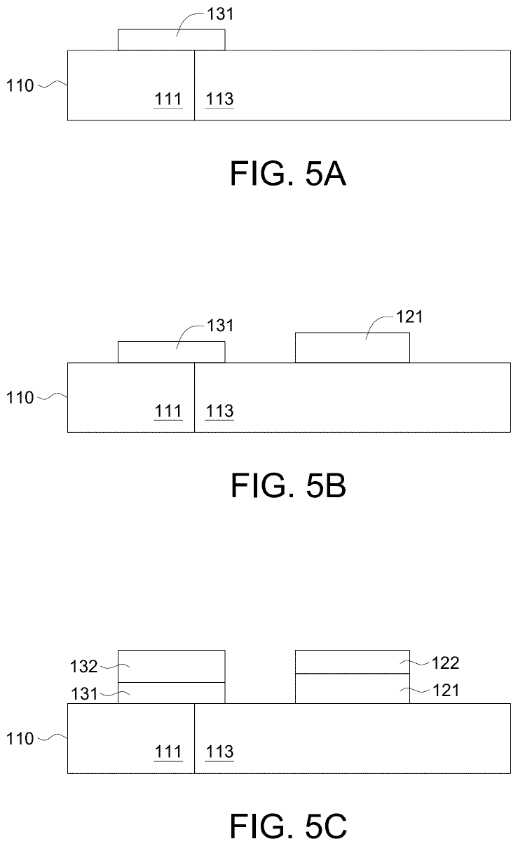

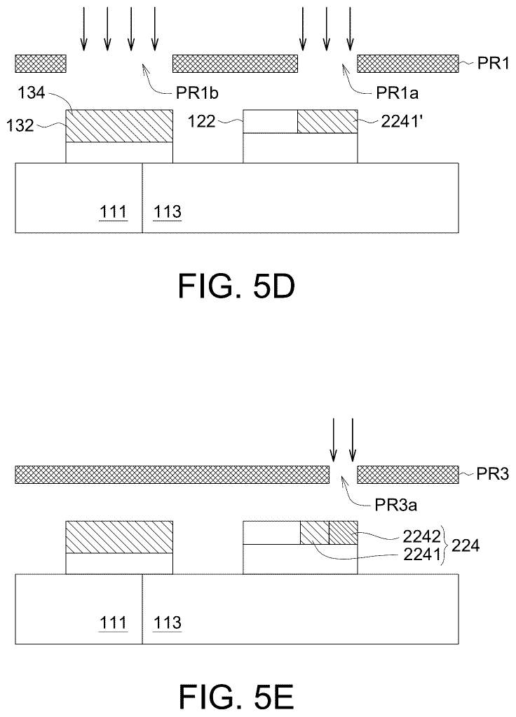

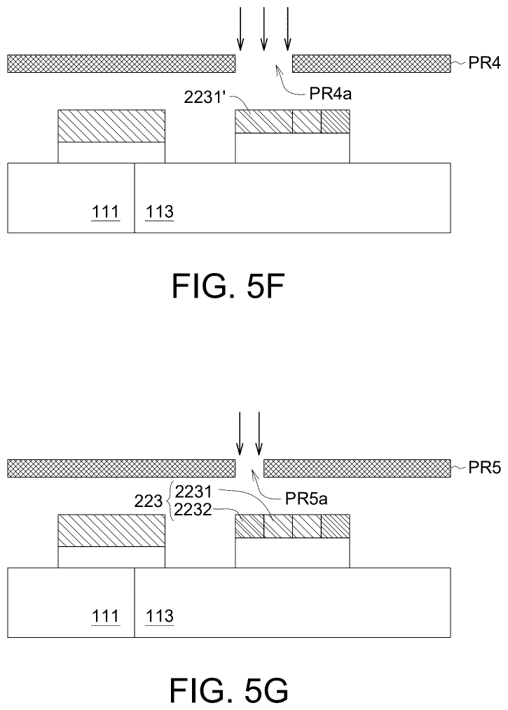

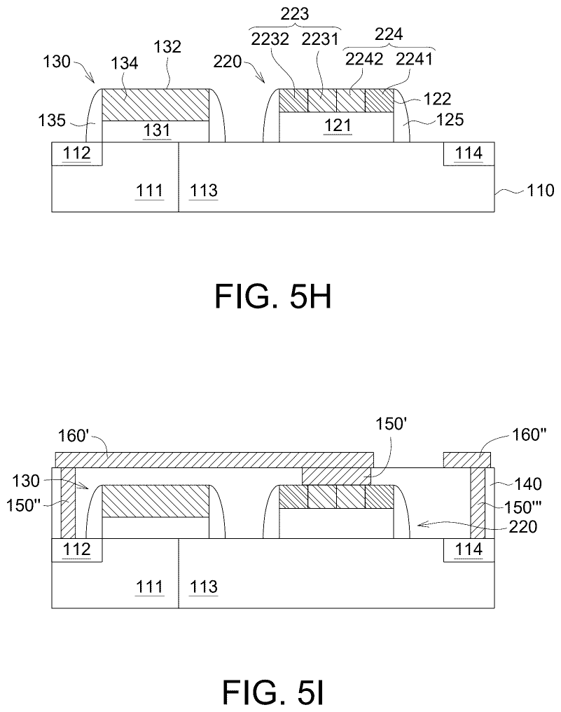

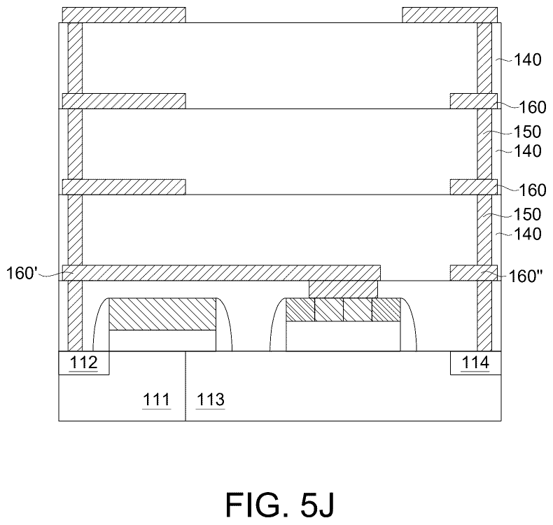

Referring to FIGS. 5A to 5J, FIGS. 5A to 5J illustrate schematic diagrams of manufacturing processes of the semiconductor structure 200 in FIG. 1B.

As illustrated in FIG. 5A, the substrate 110 including the first doping region 111 and the third doping region 113 is provided. Then, the insulation layer 131 is formed on the substrate 110 by using, for example, deposition, photolithography, etching, etc.

As illustrated in FIG. 5B, the insulation layer 121 is formed on the third doping region 113 of the substrate 110 by using, for example by using, for example, deposition, photolithography, etching, etc.

As illustrated in FIG. 5C, the poly gate 132 over the insulation layer 131 by using, for example by using, for example, deposition, photolithography, etching, etc. The poly gate 122 over the insulation layer 121 by using, for example by using, for example, deposition, photolithography, etching, etc.

As illustrated in FIG. 5D, the second sub-region 2241′ is formed within the first portion of the poly gate 122 by using, for example, implant. The semiconductor doping region 134 is formed within the poly gate 132 by using, for example, implant. The second sub-region 2241′ and the semiconductor doping region 134 may be formed through the mask PR1, wherein the mask PR1 has a first penetration zone PR1a and a second penetration zone PR1b, the second sub-region 2241′ is formed through the first penetration zone PR1a, and the semiconductor doping region 134 is formed through the second penetration zone PR1b.

As illustrated in FIG. 5E, a doping region is formed in a portion of the second sub-region 2241′ in FIG. 5D to form the second sub-region 2242 by using, for example, implant, and the other portion of the second sub-region 2241′ forms the second sub-region 2241. The second sub-region 2242 may be formed through a mask PR3, wherein the mask PR3 has a penetration zone PR3a. The second sub-region 2242 is formed through the penetration zone PR3a of the mask PR3. The second sub-region 2241 and the second sub-region 2242 may form the second-type semiconductor doping region 224.

As illustrated in FIG. 5F, the first sub-region 2232′ is formed within a second portion of the poly gate 122 by using, for example, implant. The first sub-region 2232′ may be formed through a mask PR4, wherein the mask PR4 has a penetration zone PR4a, the first sub-region 2231′ is formed through the penetration zone PR4a.

As illustrated in FIG. 5G, a doping region is formed in a portion of the first sub-region 2232′ to form the first sub-region 2231 by using, for example, implant, and the other portion of the first sub-region 2232′ forms the first sub-region 2232. The second sub-region 2242 may be formed through a mask PR5, wherein the mask PR5 has a penetration zone PR5a. The first sub-region 2231 is formed through the penetration zone PR5a of the mask PR5. The first sub-region 2231 and the first sub-region 2232 may form the first-type semiconductor doping region 223.

As Illustrated in FIG. 5h, the spacer 135 covering the lateral surface of the insulation layer 131 and the poly gate 132 is formed by using, deposition, photolithography, etching, etc. The spacer 125 covering a lateral surface of the insulation layer 121 and the poly gate 122 is formed by using, deposition, photolithography, etching, etc. The second doping region 112 in the first doping region 111 and the fourth doping region 114 in the third doping region 113 are formed by implant. So far, the contact field plate 220 and the transistor 130 are formed.

As illustrated in FIG. 5I, the dielectric layer 140 covering the contact field plate 220 and the transistor 130 is formed by using, for example, deposition, CMP. Then, the conductive via 150′, the conductive via 150″ and the conductive via 150″′ are formed in the dielectric layer 140 by using, for example, photolithography, deposition, etching, CMP, etc. Then, the conductive layer 160′ on the dielectric layer 140 is formed by using, for example, deposition, photolithography, etching, etc.

The conductive via 150′ electrically connects the poly gate 122 with the conductive layer 160′, and the conductive via 150″ electrically connects the conductive layer 160′ with the second doping region 112. In addition, the conductive via 150″′ electrically connects the fourth doping region 114 with the conductive layer 160″, and the driving voltage Vdd may be applied to the fourth doping region 114 through the conductive layer 160″ and the conductive via 150″′.

As illustrated in FIG. 5J, at least one dielectric layers 140, at least one conductive layer 160 and at least one conductive via 150 are formed on the bottommost dielectric layers 140, wherein the conductive via 150 connects two conductive layers 160.

The manufacturing method of the semiconductor structure 300 may include the steps similar to or the same as that of the semiconductor structure 200, and it will not repeated here.

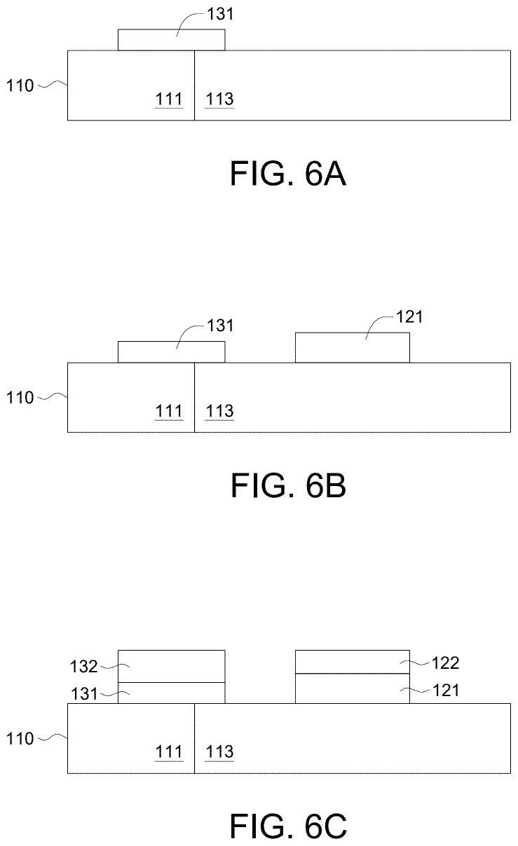

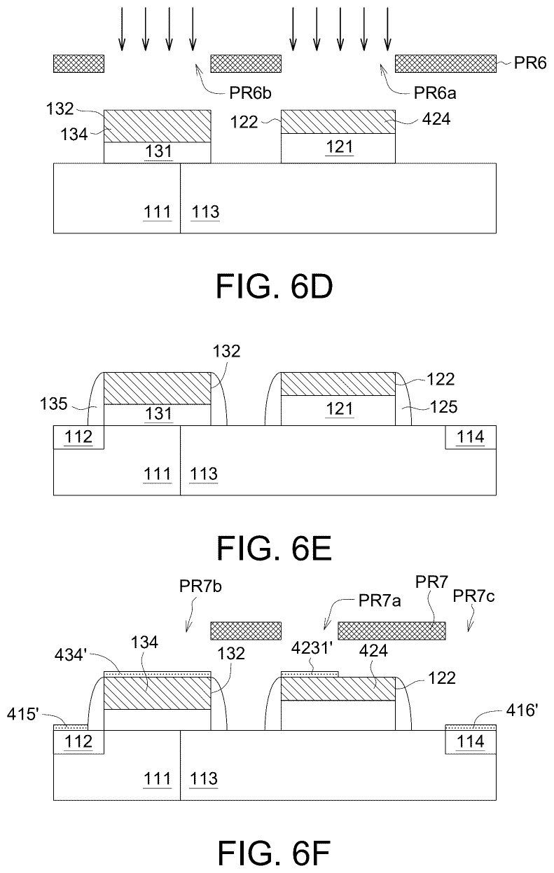

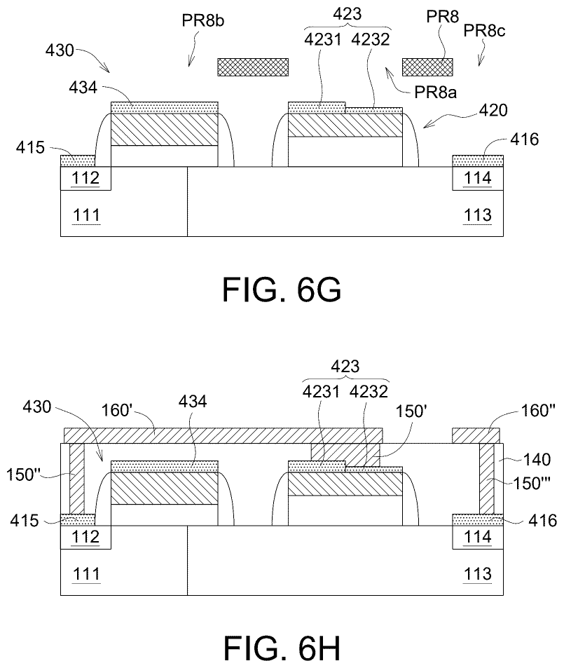

Referring to FIGS. 6A to 6I, FIGS. 6A to 6I illustrate schematic diagrams of manufacturing processes of the semiconductor structure 400 in FIG. 2A.

As illustrated in FIG. 6A, the substrate 110 including the first doping region 111 and the third doping region 113 is provided. Then, the insulation layer 131 is formed on the substrate 110 by using, for example, deposition, photolithography, etching, etc.

As illustrated in FIG. 6B, the insulation layer 121 is formed on the third doping region 113 of the substrate 110 by using, for example by using, for example, deposition, photolithography, etching, etc.

As illustrated in FIG. 6C, the poly gate 132 over the insulation layer 131 by using, for example by using, for example, deposition, photolithography, etching, etc. The poly gate 122 over the insulation layer 121 by using, for example by using, for example, deposition, photolithography, etching, etc.

As illustrated in FIG. 6D, the semiconductor doping region 424 is formed within the poly gate 122 by using, for example, implant. The semiconductor doping region 134 is formed within the poly gate 132 by using, for example, implant. The semiconductor doping region 424 and the semiconductor doping region 134 may be formed through a mask PR6, wherein the mask PR6 has a first penetration zone PR6a and a second penetration zone PR6b, the semiconductor doping region 424 is formed through the first penetration zone PR6a, and the semiconductor doping region 134 is formed through the second penetration zone PR6b.

As illustrated in FIG. 6E, the spacer 135 covering the lateral surface of the insulation layer 131 and the poly gate 132 is formed by using, deposition, photolithography, etching, etc. The spacer 125 covering the lateral surface of the insulation layer 121 and the poly gate 122 is formed by using, deposition, photolithography, etching, etc. The second doping region 112 in the first doping region 111 and the fourth doping region 114 in the third doping region 113 are formed by implant.

As illustrated in FIG. 6F, a first silicide portion 4231′ on a first portion of the poly gate 122, a silicide portion 434′ on the poly gate 132, a silicide portion 415′ on the second doping region 112 and a silicide portion 416′ on the fourth doping region 114 are formed through a mask PR7. The mask PR7 has a first penetration zone PR7a, a second penetration zone PR7b and a third penetration zone PR7c, wherein the first silicide portion 4231′ is formed through the first penetration zone PR7a, the silicide portion 434′ and the silicide portion 415′ are formed through the second penetration zone PR7b, and the silicide portion 416′ is formed through the third penetration zone PR7c.

As illustrated in FIG. 6G, the second silicide portion 4232 is formed on a second portion of the poly gate 122, a silicide portion is formed on the first silicide portion 4231′ to form the first silicide portion 4231, a silicide portion is formed on the silicide portion 415′ to form the silicide portion 415, a silicide portion is formed on the silicide portion 416′ to form the silicide portion 416 and a silicide portion is formed on the silicide portion 434′ to form the silicide portion 434. The silicide portions may be formed through a mask PR8. So far, the contact field plate 420 and the transistor 130 are formed. The mask PR8 has a first penetration zone PR8a, a second penetration zone PR8b and a third penetration zone PR8c, wherein the first silicide portion 4231, the second silicide portion 4232 are formed through the first penetration zone PR8a, the silicide portion 415 and the silicide portion 434 are formed through the second penetration zone PR8b, and the silicide portion 416 is formed through the third penetration zone PR8c.

As illustrated in FIG. 6H, the dielectric layer 140 covering the contact field plate 420 and the transistor 130 is formed by using, for example, deposition, CMP. Then, the conductive via 150′, the conductive via 150″ and the conductive via 150″′ are formed in the dielectric layer 140 by using, for example, photolithography, deposition, etching, CMP, etc. Then, the conductive layer 160′ on the dielectric layer 140 is formed by using, for example, deposition, photolithography, etching, etc.

The conductive via 150′ electrically connects the poly gate 122 with the conductive layer 160′, and the conductive via 150″ electrically connects the conductive layer 160′ with the second doping region 112. In addition, the conductive via 150″′ electrically connects the fourth doping region 114 with the conductive layer 160″, and the driving voltage Vdd may be applied to the fourth doping region 114 through the conductive layer 160″ and the conductive via 150″′.

As illustrated in FIG. 6I, at least one dielectric layers 140, at least one conductive layer 160 and at least one conductive via 150 are formed on the bottommost dielectric layers 140, wherein the conductive via 150 connects two conductive layers 160.

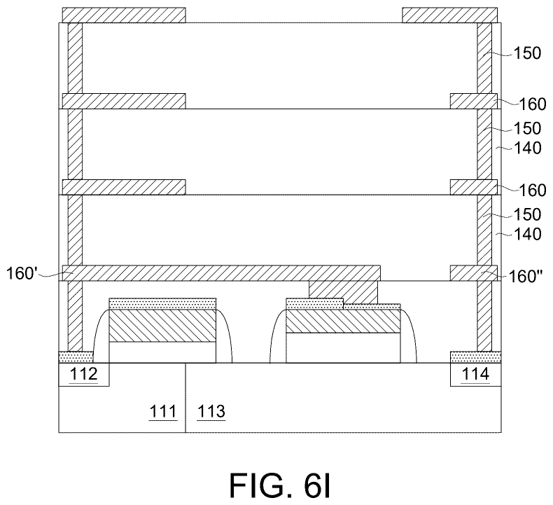

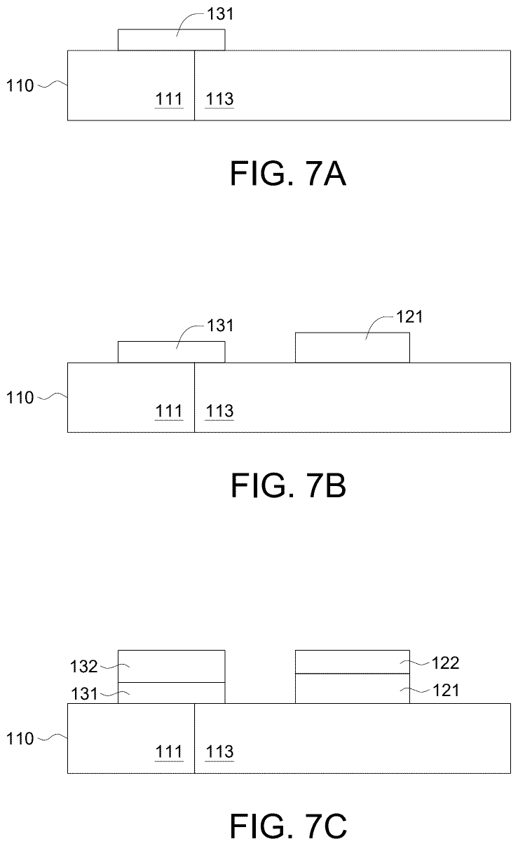

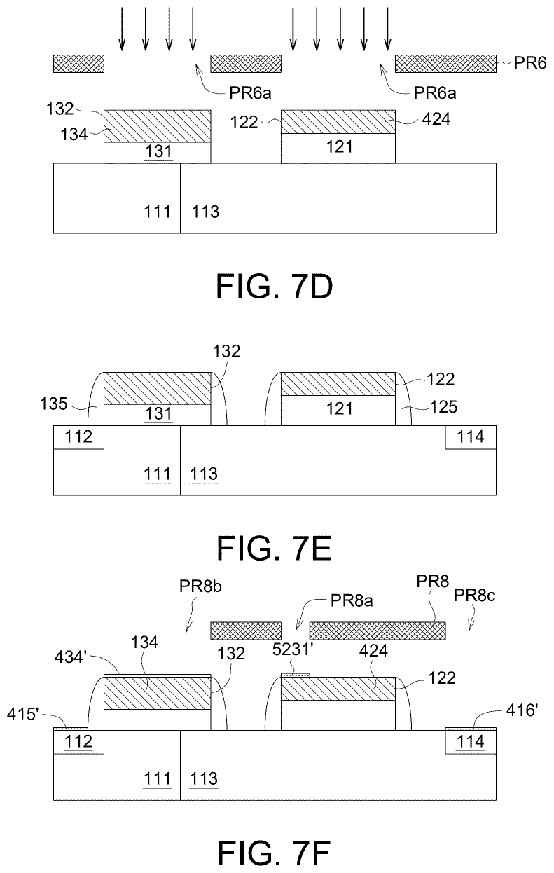

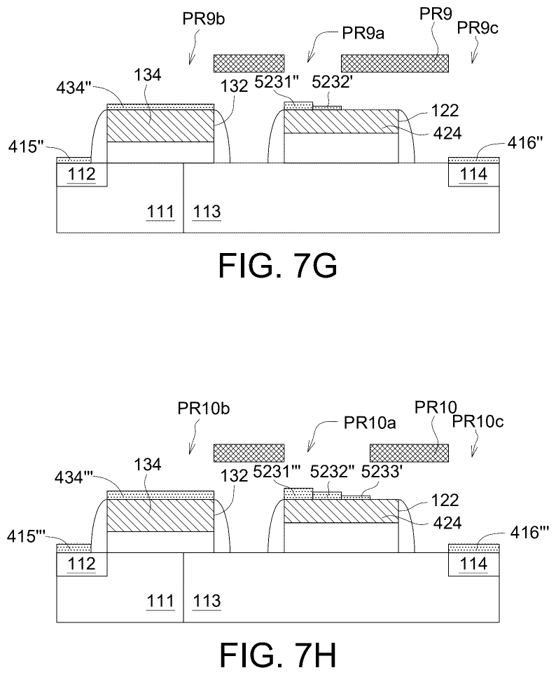

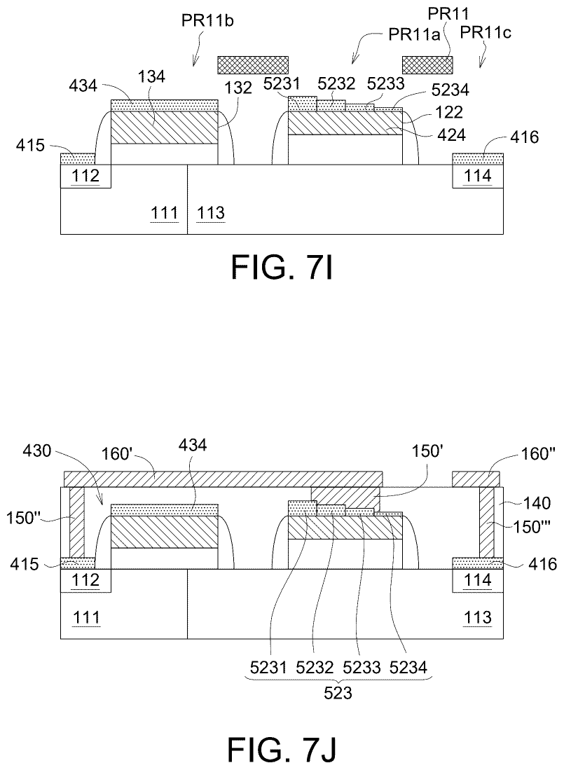

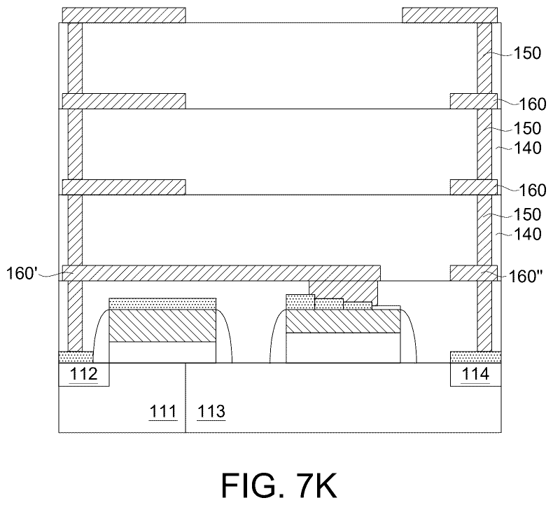

Referring to FIGS. 7A to 7K, FIGS. 7A to 7K illustrate schematic diagrams of manufacturing processes of the semiconductor structure 500 in FIG. 2B.

As illustrated in FIG. 7A, the substrate 110 including the first doping region 111 and the third doping region 113 is provided. Then, the insulation layer 131 is formed on the substrate 110 by using, for example, deposition, photolithography, etching, etc.

As illustrated in FIG. 7B, the insulation layer 121 is formed on the third doping region 113 of the substrate 110 by using, for example by using, for example, deposition, photolithography, etching, etc.

As illustrated in FIG. 7C, the poly gate 132 over the insulation layer 131 by using, for example by using, for example, deposition, photolithography, etching, etc. The poly gate 122 over the insulation layer 121 by using, for example by using, for example, deposition, photolithography, etching, etc.

As illustrated in FIG. 7D, the semiconductor doping region 424 is formed within the poly gate 122 by using, for example, implant. The semiconductor doping region 134 is formed within the poly gate 132 by using, for example, implant. The semiconductor doping region 424 and the semiconductor doping region 134 may be formed through a mask PR6, wherein the mask PR6 has a first penetration zone PR6a and a second penetration zone PR6b, the semiconductor doping region 424 is formed through the first penetration zone PR6a, and the semiconductor doping region 134 is formed through the second penetration zone PR6b.

As illustrated in FIG. 7E, the spacer 135 covering the lateral surface of the insulation layer 131 and the poly gate 132 is formed by using, deposition, photolithography, etching, etc. The spacer 125 covering the lateral surface of the insulation layer 121 and the poly gate 122 is formed by using, deposition, photolithography, etching, etc. The second doping region 112 in the first doping region 111 and the fourth doping region 114 in the third doping region 113 are formed by implant.

As illustrated in FIG. 7F, a first silicide portion 5231′ on a first portion of the poly gate 122, a silicide portion 434′ on the poly gate 132, a silicide portion 415′ on the second doping region 112 and a silicide portion 416′ on the fourth doping region 114 are formed through a mask PR8. The mask PR8 has a first penetration zone PR8a, a second penetration zone PR8b and a third penetration zone PR8c, wherein the first silicide portion 5231′ is formed through the first penetration zone PR8a, the silicide portion 434′ and the silicide portion 415′ are formed through the second penetration zone PR8b, and the silicide portion 416′ is formed through the third penetration zone PR8c.

As illustrated in FIG. 7G, a second silicide portion 5232′ is formed on a second portion the poly gate 122, a silicide portion is formed on the first silicide portion 5231′ in FIG. 7F to form a first silicide portion 5231'', a silicide portion is formed on the silicide portion 434′ in FIG. 7F to form the silicide portion 434″, a silicide portion is formed on the silicide portion 415′ in FIG. 7F to form the silicide portion 415″, and a silicide portion is formed on the silicide portion 416′ in FIG. 7F to form the silicide portion 416″. The second silicide portion 5232', the first silicide portion 5231″, the silicide portion 434″, the silicide portion 415″ and the silicide portion 416″ are formed through a mask PR9. The mask PR9 has a first penetration zone PR9a, a second penetration zone PR9b and a third penetration zone PR9c, wherein the first silicide portion 5231″ and the second silicide portion 5232′ are formed through the first penetration zone PR9a, the silicide portion 434″ and the silicide portion 415″ are formed through the second penetration zone PR9b, and the silicide portion 416″ is formed through the third penetration zone PR9c.

As illustrated in FIG. 7H, a third silicide portion 5233′ is formed on a third portion of the poly gate 122, a silicide portion is formed on the first silicide portion 5231″ in FIG. 7G to form a first silicide portion 5231′″, a silicide portion is formed on the second silicide portion 5232′ in FIG. 7G to form the second silicide portion 5232″, a silicide portion is formed on the silicide portion 434″ in FIG. 7G to form the silicide portion 434′″, a silicide portion is formed on the silicide portion 415″ in FIG. 7G to form the silicide portion 415′″, and a silicide portion is formed on the silicide portion 416″ in FIG. 7G to form the silicide portion 416′″. The third silicide portion 5233′, the second silicide portion 5232″, the first silicide portion 5231′″, the silicide portion 434′″, the silicide portion 415″′ and the silicide portion 416″′ are formed through a mask PR10. The mask PR10 has a first penetration zone PR10a, a second penetration zone PR10b and a third penetration zone PR10c, wherein the third silicide portion 5233', the first silicide portion 5231″′ and the second silicide portion 5232″ are formed through the first penetration zone PR10a, the silicide portion 434″′ and the silicide portion 415″′ are formed through the second penetration zone PR10b, and the silicide portion 416″′ is formed through the third penetration zone PR10c.

As illustrated in FIG. 7I, a fourth silicide portion 5234 is formed on a fourth portion of the poly gate 122, a silicide portion is formed on the third silicide portion 5233′ to form the third silicide portion 5233, a silicide portion is formed on the first silicide portion 5231″′ to form the first silicide portion 5231, a silicide portion is formed on the second silicide portion 5232″ to form the second silicide portion 5232, a silicide portion is formed on the silicide portion 434″′ to form the silicide portion 434, a silicide portion is formed on the silicide portion 415″′ to form the silicide portion 415, and a silicide portion is formed on the silicide portion 416″′ to form the silicide portion 416. The fourth silicide portion 5234, the third silicide portion 5233, the second silicide portion 5232, the first silicide portion 5231, the silicide portion 434, the silicide portion 415 and the silicide portion 416 are formed through a mask PR11. The mask PR11 has a first penetration zone PR11a, a second penetration zone PR11b and a third penetration zone PR11c, wherein the fourth silicide portion 5234, the third silicide portion 5233, the first silicide portion 5231 and the second silicide portion 5232 are formed through the first penetration zone PR11a, the silicide portion 434 and the silicide portion 415 are formed through the second penetration zone PR11b, and the silicide portion 416 is formed through the third penetration zone PR11c.

As illustrated in FIG. 7J, the dielectric layer 140 covering the contact field plate 420 and the transistor 130 is formed by using, for example, deposition, CMP. Then, the conductive via 150′, the conductive via 150″ and the conductive via 150″′ are formed in the dielectric layer 140 by using, for example, photolithography, deposition, etching, CMP, etc. Then, the conductive layer 160′ on the dielectric layer 140 is formed by using, for example, deposition, photolithography, etching, etc.

The conductive via 150′ electrically connects the poly gate 122 with the conductive layer 160′, and the conductive via 150″ electrically connects the conductive layer 160′ with the second doping region 112. In addition, the conductive via 150″′ electrically connects the fourth doping region 114 with the conductive layer 160″, and the driving voltage Vdd may be applied to the fourth doping region 114 through the conductive layer 160″ and the conductive via 150″′.

As illustrated in FIG. 7K, at least one dielectric layers 140, at least one conductive layer 160 and at least one conductive via 150 are formed on the bottommost dielectric layers 140, wherein the conductive via 150 connects two conductive layers 160.

The manufacturing method of the semiconductor structure 600 may include the steps similar to or the same as that of the semiconductor structure 500, and it will not repeated here.

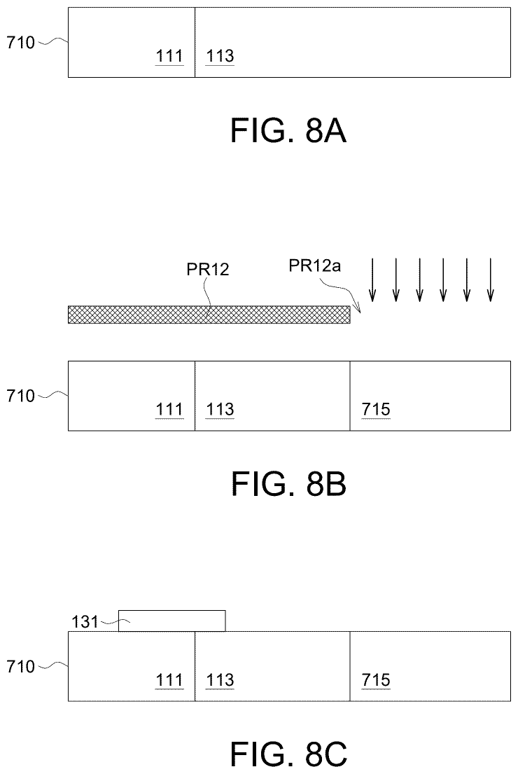

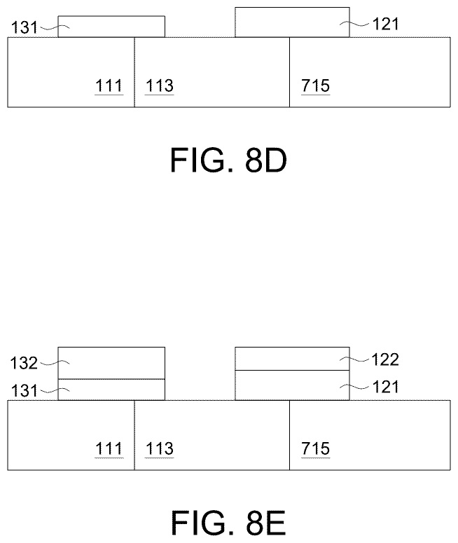

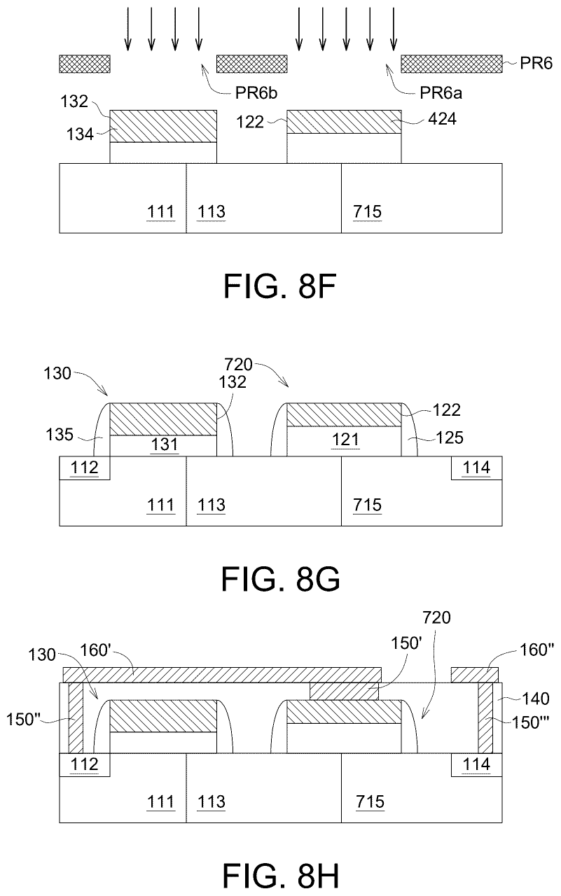

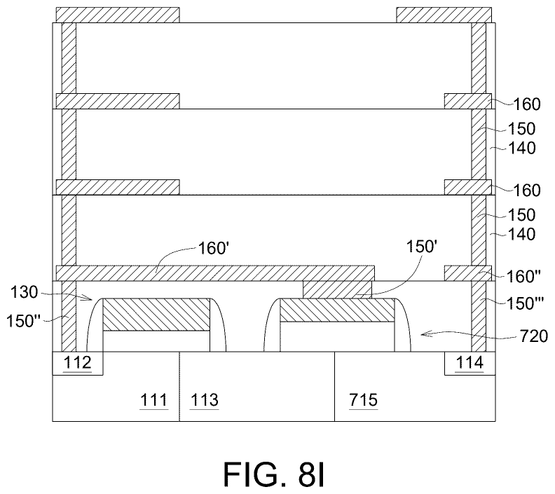

Referring to FIGS. 8A to 8I, FIGS. 8A to 8I illustrate schematic diagrams of manufacturing processes of the semiconductor structure 700 in FIG. 3.

As illustrated in FIG. 8A, the substrate 710 including the first doping region 111 and the third doping region 113 is provided. Then, the insulation layer 131 is formed on the substrate 710 by using, for example, deposition, photolithography, etching, etc.

As illustrated in FIG. 8B, the fifth doping region 715 is formed in the insulation layer 131 by using, for example, implant. The fifth doping region 715 is formed through a mask PR12, wherein the mask PR12 has a penetration zone PR12a, and the fifth doping region 715 is formed through the penetration zone PR12a.

As illustrated in FIG. 8C, the insulation layer 131 is formed on the substrate 710 by using, for example, deposition, photolithography, etching, etc.

As illustrated in FIG. 8D, the insulation layer 121 is formed on the third doping region 113 and the fifth doping region 715 of the substrate 710 by using, for example by using, for example, deposition, photolithography, etching, etc. The insulation layer 121 is located above the insulation layer 131 and the fifth doping region 715.

As illustrated in FIG. 8E, the poly gate 132 over the insulation layer 131 by using, for example by using, for example, deposition, photolithography, etching, etc. The poly gate 122 over the insulation layer 121 by using, for example by using, for example, deposition, photolithography, etching, etc.

As illustrated in FIG. 8F, the semiconductor doping region 424 is formed within the poly gate 122 by using, for example, implant. The semiconductor doping region 134 is formed within the poly gate 132 by using, for example, implant. The semiconductor doping region 424 and the semiconductor doping region 134 may be formed through the mask PR6, wherein the mask PR6 has the first penetration zone PR6a and a second penetration zone PR6b, the semiconductor doping region 424 is formed through the first penetration zone PR6a, and the semiconductor doping region 134 is formed through the second penetration zone PR6b.

As illustrated in FIG. 8H, the spacer 135 covering the lateral surface of the insulation layer 131 and the poly gate 132 is formed by using, deposition, photolithography, etching, etc. The spacer 125 covering the lateral surface of the insulation layer 121 and the poly gate 122 is formed by using, deposition, photolithography, etching, etc. The second doping region 112 in the first doping region 111 and the fourth doping region 114 in the third doping region 113 are formed by implant.

As illustrated in FIG. 8I, the dielectric layer 140 covering the contact field plate 720 and the transistor 130 is formed by using, for example, deposition, CMP. Then, the conductive via 150′, the conductive via 150″ and the conductive via 150″′ are formed in the dielectric layer 140 by using, for example, photolithography, deposition, etching, CMP, etc. Then, the conductive layer 160′ on the dielectric layer 140 is formed by using, for example, deposition, photolithography, etching, etc.

The conductive via 150′ electrically connects the poly gate 122 with the conductive layer 160′, and the conductive via 150″ electrically connects the conductive layer 160′ with the second doping region 112. In addition, the conductive via 150″′ electrically connects the fourth doping region 114 with the conductive layer 160″, and the driving voltage Vdd may be applied to the fourth doping region 114 through the conductive layer 160″ and the conductive via 150″′.

As illustrated in FIG. 8I, at least one dielectric layers 140, at least one conductive layer 160 and at least one conductive via 150 are formed on the bottommost dielectric layers 140, wherein the conductive via 150 connects two conductive layers 160.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor structure includes a substrate and a contact field plate on the substrate. The contact field plate includes an insulation layer on the substrate, a poly gate over the insulation layer, a first-type semiconductor doping region in the poly gate, and a second-type semiconductor doping region in the poly gate. Accordingly, the first-type semiconductor doping region and the second-type semiconductor doping region may split electrons deplete condition (split electric field) for increasing the voltage (for example, breakdown voltage) endurance capability of the contact field plate.

Example embodiment 1: a semiconductor structure includes a substrate and a contact field plate (CFP) on the substrate. The contact field plate includes an insulation layer on the substrate, a poly gate over the insulation layer, a first-type semiconductor doping region in the poly gate, and a second-type semiconductor doping region in the poly gate.

Example embodiment 2 based on Example embodiment 1: the first-type semiconductor doping region has a first length, the second-type semiconductor doping region has a second length, and the second length is equal to the first length.

Example embodiment 3 based on Example embodiment 1: the first-type semiconductor doping region includes a plurality of first sub-regions, and the first sub-regions respectively have different doping concentrations.

Example embodiment 4 based on Example embodiment 3: a first one of the first sub-regions is closer to the second-type semiconductor doping region than a second one of the first sub-regions, and the first one of the first sub-regions has a doping concentration less than that of the second one of the first sub-regions.

Example embodiment 5 based on Example embodiment 4: the first one of the first sub-regions has a first sub-length equal to that of the second one of the first sub-regions.

Example embodiment 6 based on Example embodiment 1: the second-type semiconductor doping region includes a plurality of second sub-regions, and the second sub-regions respectively have different doping concentrations.

Example embodiment 7 based on Example embodiment 6: a first one of the second sub-regions is closer to the first-type semiconductor doping region than a second one of the second sub-regions, and the first one of the second sub-regions has a doping concentration less than that of the second one of the second sub-regions.

Example embodiment 8 based on Example embodiment 7: the first one of the second sub-regions has a second sub-length equal to that of the second one of the second sub-regions.

Example embodiment 9 based on Example embodiment 1: the first-type semiconductor doping region and the second-type semiconductor doping region are disposed side-by-side.

Example embodiment 10: a semiconductor structure includes a substrate and a contact field plate on the substrate. The contact field plate includes an insulation layer on the substrate, a poly gate over the insulation layer and a silicide over the poly gate. The silicide includes a first silicide portion having a first thickness and a second silicide portion having a second thickness. The first thickness and the second thickness are different.

Example embodiment 11 based on Example embodiment 10: the semiconductor structure further includes a NMOS transistor on the substrate. The first silicide portion is closer to the NMOS transistor than the second silicide portion, and the first thickness is greater than the second thickness.

Example embodiment 12 based on Example embodiment 10: the semiconductor structure further includes a PMOS transistor on the substrate. The first silicide portion is closer to the PMOS transistor than the second silicide portion, and the first thickness is less than the second thickness.

Example embodiment 13 based on Example embodiment 10: the first silicide portion has a first length, the second silicide portion has a second length, and the first length is equal to the second length.

Example embodiment 14 based on Example embodiment 10: the silicide further includes a third silicide portion having a third thickness. The second silicide portion is disposed between the first silicide portion and the third silicide portion, and the third thickness ranges between the first thickness and the second thickness.

Example embodiment 15 based on Example embodiment 14: the first silicide portion has a first length, the second silicide portion has a second length, the third silicide portion has a third length, and the first length, the second length and the third length are equal.

Example embodiment 16 based on Example embodiment 10: the first silicide portion and the second silicide portion are disposed side-by-side.

Example embodiment 17: a semiconductor structure includes a substrate and a contact field plate. The substrate includes a plurality of doping regions, wherein the doping regions have different doping concentrations. The contact field plate on the substrate and above the doping regions.

Example embodiment 18 based on Example embodiment 17: the substrate further includes a semiconductor well, and the semiconductor structure further includes a transistor on the semiconductor well. A first one of the doping regions is located between the semiconductor well and a second one of the doping regions, and the second one has a doping concentration greater than that of the first one.

Example embodiment 19 based on Example embodiment 17: the contact field plate has a first length and a second length, the first length overlap the first one of the doping regions, the second length overlap the second one of the doping regions, and the first length is equal to the second length.

Example embodiment 20 based on Example embodiment 17: the doping regions are disposed side by side.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate; and
a contact field plate (CFP) on the substrate, comprising:
an insulation layer on the substrate;
a poly gate over the insulation layer;
a first-type semiconductor doping region in the poly gate; and
a second-type semiconductor doping region in the poly gate.

2. The semiconductor structure according to claim 1, wherein the first-type semiconductor doping region has a first length, the second-type semiconductor doping region has a second length, and the second length is equal to the first length.

3. The semiconductor structure according to claim 1, wherein the first-type semiconductor doping region comprising a plurality of first sub-regions, and the first sub-regions respectively have different doping concentrations.

4. The semiconductor structure according to claim 3, wherein a first one of the first sub-regions is closer to the second-type semiconductor doping region than a second one of the first sub-regions, and the first one of the first sub-regions has a doping concentration less than that of the second one of the first sub-regions.

5. The semiconductor structure according to claim 4, wherein the first one of the first sub-regions has a first sub-length equal to that of the second one of the first sub-regions.

6. The semiconductor structure according to claim 1, wherein the second-type semiconductor doping region comprising a plurality of second sub-regions, and the second sub-regions respectively have different doping concentrations.

7. The semiconductor structure according to claim 6, wherein a first one of the second sub-regions is closer to the first-type semiconductor doping region than a second one of the second sub-regions, and the first one of the second sub-regions has a doping concentration less than that of the second one of the second sub-regions.

8. The semiconductor structure according to claim 7, wherein the first one of the second sub-regions has a second sub-length equal to that of the second one of the second sub-regions.

9. The semiconductor structure according to claim 1, wherein the first-type semiconductor doping region and the second-type semiconductor doping region are disposed side-by-side.

10. A semiconductor structure, comprising:
a substrate; and
a contact field plate on the substrate, comprising:
an insulation layer on the substrate;
a poly gate over the insulation layer; and
a silicide over the poly gate, comprising:
a first silicide portion having a first thickness; and
a second silicide portion having a second thickness;
wherein the first thickness and the second thickness are different.

11. The semiconductor structure according to claim 10, further comprising:
a NMOS transistor on the substrate;
wherein the first silicide portion is closer to the NMOS transistor than the second silicide portion, and the first thickness is greater than the second thickness.

12. The semiconductor structure according to claim 10, further comprising:
a PMOS transistor on the substrate;
wherein the first silicide portion is closer to the PMOS transistor than the second silicide portion, and the first thickness is less than the second thickness.

13. The semiconductor structure according to claim 10, wherein the first silicide portion has a first length, the second silicide portion has a second length, and the first length is equal to the second length.

14. The semiconductor structure according to claim 10, wherein the silicide further
comprises:
a third silicide portion having a third thickness;
wherein the second silicide portion is disposed between the first silicide portion and the third silicide portion, and the third thickness ranges between the first thickness and the second thickness.

15. The semiconductor structure according to claim 14, wherein the first silicide portion has a first length, the second silicide portion has a second length, the third silicide portion has a third length, and the first length, the second length and the third length are equal.

16. The semiconductor structure according to claim 10, wherein the first silicide portion and the second silicide portion are disposed side-by-side.

17. A semiconductor structure, comprising:
a substrate comprising a plurality of doping regions, wherein the doping regions have different doping concentrations; and
a contact field plate on the substrate and above the doping regions.

18. The semiconductor structure according to claim 17, wherein the substrate further
comprises a semiconductor well, and the semiconductor structure further comprises:
a transistor on the semiconductor well;
wherein a first one of the doping regions is located between the semiconductor well and a second one of the doping regions, and the second one has a doping concentration greater than that of the first one.

19. The semiconductor structure according to claim 17, wherein the contact field plate has a first length and a second length, the first length overlap the first one of the doping regions, the second length overlap the second one of the doping regions, and the first length is equal to the second length.

20. The semiconductor structure according to claim 17, wherein the doping regions are disposed side by side.
